(19) United States
(12) Patent Application Publication
(10) Pub. No.: US 2025/0291970 A1
(43) Pub. Date: Sep. 18, 2025

(54) EXTRAPOLATION AND INTERACTIONS OF DIGITAL TWIN-BASED MODELS AND APPLICATIONS

(71) Applicant: QUALCOMM Incorporated, San Diego, CA (US)

(72) Inventors: Himaja KESAVAREDDIGARI, Bridgewater, NJ (US); Qing LI, Princeton Junction, NJ (US); Hong CHENG, Basking Ridge, NJ (US); Kapil GULATI, Belle Mead, NJ (US); Preeti KUMARI, San Diego, CA (US)

(21) Appl. No.: 18/608,773

(22) Filed: Mar. 18, 2024

(51) Int. Cl. G06F 30/20; H04W 24/08

(52) U.S. Cl. CPC G06F 30/20; H04W 24/08

(57) ABSTRACT

Systems and techniques for wireless communications are described herein. For example, a network entity can determine one or more tracking elements based on detection of a change in data elements within an area of interest in a real-world environment of a user equipment (UE). The one or more tracking elements can include estimates of an impact of the change to one or more applications in the area of interest and one or more characteristics of the change. The network entity can determine, based on the impact of the change and the one or more characteristics of the change, whether to determine one or more new or existing digital twin models for a smaller target area within the area of interest or to modify one or more existing digital twin models for the area of interest.

### FIELD

The present disclosure generally relates to wireless communications. For example, aspects of the present disclosure relate to extrapolation and interactions (e.g., in real-time or near-real-time) of digital twin-based models and applications.

### BACKGROUND

Wireless communications systems are deployed to provide various telecommunication services, including telephony, video, data, messaging, broadcasts, among others. Wireless communications systems have developed through various generations, including a first-generation analog wireless phone service (1G), a second-generation (2G) digital wireless phone service (including interim 2.5G networks), a third-generation (3G) high speed data, Internet-capable wireless service, a fourth-generation (4G) service (e.g., Long-Term Evolution (LTE), WiMax), and a fifth-generation (5G) service (e.g., New Radio (NR)). There are presently many different types of wireless communications systems in use, including cellular and personal communications service (PCS) systems. Examples of known cellular systems include the cellular Analog Advanced Mobile Phone System (AMPS), and digital cellular systems based on code division multiple access (CDMA), frequency division multiple access (FDMA), time division multiple access (TDMA), the Global System for Mobile communication (GSM), etc.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

Disclosed are systems, apparatuses, methods and computer-readable media for real-time extrapolation and interactions of digital twin-based models and applications. According to at least one example, a network entity for wireless communications is provided. The network entity includes at least one memory and at least one processor coupled to the at least one memory and configured to: determine one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and determine, based on the impact of the change and the one or more characteristics of the change, whether to determine one or more new or existing digital twin models for a smaller target area within the area of interest or to modify one or more existing digital twin models for the area of interest.

In another illustrative example, a method is provided for wireless communications. The method includes: determining, by a network entity, one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and determining, by the network entity based on the impact of the change and the one or more characteristics of the change, whether to determine one or more new or existing digital twin models for a smaller target area within the area of interest or to modify one or more existing digital twin models for the area of interest.

In another illustrative example, a non-transitory computer-readable medium of a network entity is provided having stored thereon instructions that, when executed by at least one processor, cause the at least one processor to: determine one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and determine, based on the impact of the change and the one or more characteristics of the change, whether to determine one or more new or existing digital twin models for a smaller target area within the area of interest or to modify one or more existing digital twin models for the area of interest.

In another illustrative example, a network entity for wireless communications is provided. The apparatus includes: means for determining, by a network entity, one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and means for determining, by the network entity based on the impact of the change and the one or more characteristics of the change, whether to determine one or more new or existing digital twin models for a smaller target area within the area of interest or to modify one or more existing digital twin models for the area of interest.

In another illustrative example, a network device (e.g., a user equipment (UE)) for wireless communications is provided. The network device includes at least one memory and at least one processor coupled to the at least one memory and configured to: output a digital twin interaction request for transmission to a network entity based on detection of a change in an area of interest in a real-world environment of the network device; receive a first set of parameters from the network entity; output a first set of data elements for transmission to the network entity based on the first set of parameters; receive a second set of parameters from the network entity based on the digital twin interaction request and the first set of data elements; output a second set of data elements for transmission to the network entity based on the second set of parameters; and receive, from the network entity, one or more outputs of a server configured for performing machine learning (ML) and non-ML algorithms, based on the first set of parameters, the second set of parameters, the first set of data elements, and the second set of data elements.

In another illustrative example, a method for wireless communications is provided. The method includes: transmitting, by a network device, a digital twin interaction request to a network entity based on detection of a change in an area of interest in a real-world environment of the network device; receiving, by the network device, a first set of parameters from the network entity; transmitting, by the network device, a first set of data elements to the network entity based on the first set of parameters; receiving, by the network device, a second set of parameters from the network entity based on the digital twin interaction request and the first set of data elements; transmitting, by the network device, a second set of data elements to the network entity based on the second set of parameters; and receiving, by the network device from the network entity, one or more outputs of a server configured for performing machine learning (ML) and non-ML algorithms, based on the first set of parameters, the second set of parameters, the first set of data elements, and the second set of data elements.

In another illustrative example, a non-transitory computer-readable medium of a network device is provided having stored thereon instructions that, when executed by at least one processor, cause the at least one processor: output a digital twin interaction request for transmission to a network entity based on detection of a change in an area of interest in a real-world environment of the network device; receive a first set of parameters from the network entity; output a first set of data elements for transmission to the network entity based on the first set of parameters; receive a second set of parameters from the network entity based on the digital twin interaction request and the first set of data elements; output a second set of data elements for transmission to the network entity based on the second set of parameters; and receive, from the network entity, one or more outputs of a server configured for performing machine learning (ML) and non-ML algorithms, based on the first set of parameters, the second set of parameters, the first set of data elements, and the second set of data elements.

In another illustrative example, a network device for wireless communications is provided. The apparatus includes: means for transmitting, by a network device, a digital twin interaction request to a network entity based on detection of a change in an area of interest in a real-world environment of the network device; means for receiving, by the network device, a first set of parameters from the network entity; means for transmitting, by the network device, a first set of data elements to the network entity based on the first set of parameters; means for receiving, by the network device, a second set of parameters from the network entity based on the digital twin interaction request and the first set of data elements; means for transmitting, by the network device, a second set of data elements to the network entity based on the second set of parameters; and means for receiving, by the network device from the network entity, one or more outputs of a server configured for performing machine learning (ML) and non-ML algorithms, based on the first set of parameters, the second set of parameters, the first set of data elements, and the second set of data elements.

Aspects generally include a method, apparatus, system, computer program product, non-transitory computer-readable medium, user device, user equipment, wireless communication device, and/or processing system as substantially described with reference to and as illustrated by the drawings and specification.

In some aspects, each of the apparatuses described above is, can be part of, or can include a mobile device, a smart or connected device, a camera system, and/or an extended reality (XR) device (e.g., a virtual reality (VR) device, an augmented reality (AR) device, or a mixed reality (MR) device). In some examples, the apparatuses can include or be part of a vehicle, a mobile device (e.g., a mobile telephone or so-called “smart phone” or other mobile device), a wearable device, a personal computer, a laptop computer, a tablet computer, a server computer, a robotics device or system, an aviation system, or other device. In some aspects, the apparatus includes an image sensor (e.g., a camera) or multiple image sensors (e.g., multiple cameras) for capturing one or more images. In some aspects, the apparatus includes one or more displays for displaying one or more images, notifications, and/or other displayable data. In some aspects, the apparatus includes one or more speakers, one or more light-emitting devices, and/or one or more microphones. In some aspects, the apparatuses described above can include one or more sensors. In some cases, the one or more sensors can be used for determining a location of the apparatuses, a state of the apparatuses (e.g., a tracking state, an operating state, a temperature, a humidity level, and/or other state), and/or for other purposes.

Some aspects include a device having a processor configured to perform one or more operations of any of the methods summarized above. Further aspects include processing devices for use in a device configured with processor-executable instructions to perform operations of any of the methods summarized above. Further aspects include a non-transitory processor-readable storage medium having stored thereon processor-executable instructions configured to cause a processor of a device to perform operations of any of the methods summarized above. Further aspects include a device having means for performing functions of any of the methods summarized above.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims. The foregoing, together with other features and aspects, will become more apparent upon referring to the following specification, claims, and accompanying drawings.

This summary is not intended to identify key or essential features of the claimed subject matter, nor is it intended to be used in isolation to determine the scope of the claimed subject matter. The subject matter should be understood by reference to appropriate portions of the entire specification of this patent, any or all drawings, and each claim.

The preceding, together with other features and embodiments, will become more apparent upon referring to the following specification, claims, and accompanying drawings.

### BRIEF DESCRIPTION OF THE DRAWINGS

Illustrative aspects of the present application are described in detail below with reference to the following figures:

FIG. 1 is a block diagram illustrating an example of a wireless communication network, in accordance with some examples.

FIG. 2 is a diagram illustrating a design of a base station and a User Equipment (UE) device that enable transmission and processing of signals exchanged between the UE and the base station, in accordance with some examples.

FIG. 3 is a diagram illustrating an example of a disaggregated base station, in accordance with some examples.

FIG. 4 is a block diagram illustrating an example of a computing system of a vehicle, in accordance with some examples.

FIG. 5 is a diagram illustrating an example of a process for the creation of one or more digital twin-based models for an area of interest in a real-world environment, in accordance with some examples.

FIG. 6 is a diagram illustrating an example of a process for the real-time extrapolation of digital twin-based models and applications, in accordance with some examples.

FIG. 7 is a diagram illustrating an example of a process for the real-time interactions of digital twin-based models and applications, in accordance with some examples.

FIG. 8 is a flow diagram illustrating an example of a process for real-time extrapolation of digital twin-based models and applications, in accordance with some examples.

FIG. 9 is a flow diagram illustrating an example of a process for real-time interactions of digital twin-based models and applications, in accordance with some examples.

FIG. 10 is a diagram illustrating an example of a system for implementing certain aspects described herein.

### DETAILED DESCRIPTION

Certain aspects of this disclosure are provided below for illustration purposes. Alternate aspects may be devised without departing from the scope of the disclosure. Additionally, well-known elements of the disclosure will not be described in detail or will be omitted so as not to obscure the relevant details of the disclosure. Some of the aspects described herein can be applied independently and some of them may be applied in combination as would be apparent to those of skill in the art. In the following description, for the purposes of explanation, specific details are set forth in order to provide a thorough understanding of aspects of the application. However, it will be apparent that various aspects may be practiced without these specific details. The figures and description are not intended to be restrictive.

The ensuing description provides example aspects only, and is not intended to limit the scope, applicability, or configuration of the disclosure. Rather, the ensuing description of the example aspects will provide those skilled in the art with an enabling description for implementing an example aspect. It should be understood that various changes may be made in the function and arrangement of elements without departing from the spirit and scope of the application as set forth in the appended claims.

The terms “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

A digital twin is a digital model, or a virtual model, designed to accurately reflect a real-world physical object (e.g., a vehicle), system, or process of a physical digital twin. A digital twin can serve as an effectively indistinguishable digital model of its associated counterpart physical twin (e.g., a vehicle), and can used for simulation, integration, testing, monitoring, and maintenance of the associated counterpart physical twin. A digital twin can be used throughout the lifecycle (e.g., innovation, design, build, testing, and operation) of the physical twin that the digital twin represents to model and simulate operation of the physical twin. As such, the digital twin can be created before the build of its associated physical twin. A digital twin of an existing physical twin can be used in real-time to determine modifications to be made to the physical twin and to synchronize the physical twin to its corresponding physical system.

A digital twin can update its status to be in accordance with the current status of its counterpart physical twin. For example, when sensors in the vicinity of the physical twin collect data, the sensor data can be used to update the digital twin in real time with the same state of the physical twin. A digital twin is meant to have an accurate representation of the physical twin's properties and states, including shape, position, status, and motion.

A digital twin can also be used for monitoring, diagnosis, and prognosis to optimize performance and utilization of its counterpart physical twin. Sensor data can be combined with historical data and simulation learning to improve the outcome of the prognosis. As such, intelligent maintenance systems can employ digital twins to determine causes of issues and improve productivity. For example, digital twins of autonomous vehicles and their associated sensors along with digital twins of the associated environment have been used for development, testing, and validation challenges for the automotive applications, especially when the related algorithms are based on machine learning (ML) approaches that require extensive training data and validation data sets.

There are various different types of digital twins. It is common to have different types of digital twins co-exist with each other. Different types of digital twins can include unit twins, system twins, and environment twins. When two or more components work together, they form a unit, such as user equipment (UE). A unit twin, such as a digital twin of a UE (uDT), can be used to study the interaction of those components, which can create a wealth of performance data that can be processed and then turned into actionable insights. A system twin, such as an operating digital twin (oDT), can show how different units (e.g., UEs) function together to form an entire functioning system. System twins provide visibility regarding the interaction of units, and can suggest performance enhancements. An environment twin, which is a digital twin of the environment (eDT), can be used to model a real-world environment of units (e.g., UEs). Environment twins can be used to shows how the environment impacts the units (e.g., UEs).

Currently, digital twins are extensively used in many different applications. For example, digital twins are used in power-generation equipment, such as jet engines, locomotive engines, and power-generation turbine engines. The use of digital twins for power-generation equipment can help to establish timeframes for regularly needed maintenance. For another example, digital twins are used in structures and their systems. Large physical structures, such as large buildings or offshore drilling platforms, can be improved through the use of digital twins, particularly during their design phase. Digital twins are also useful in the designing of the systems operating within those structures, such as heating, ventilation, and air conditioning (HVAC) systems. As another example, digital twins are used for manufacturing operations. Since digital twins can mirror the entire lifecycle of a product, digital twins have been used in all stages of manufacturing to guide products from the design phase to the finished product, as well as all of the steps in between. In another example, digital twins are used in healthcare services. Sensor-generated data of a patient can be used track a variety of health indicators and generate key insights to a patient's health. As another example, digital twins are used in the automotive industry. Digital twins are used extensively in auto design, both to improve vehicle performance and increase the efficiency surrounding their production. For another example, digital twins are used in urban planning. The use of digital twins can show three-dimensional (3D) spatial data in real time, and also incorporate augmented reality systems into built environments.

Physical entities (e.g., a UE, such as in the form of a vehicle) may be impacted by changes within their real-world environment. The nature (e.g., characteristics) of changes in the real-world environment may include temporary changes (e.g., roadblocks and/or parked cars), permanent changes (e.g., new structures and/or downed trees), recurrent changes (e.g., traffic patterns and/or changes in visibility), non-recurrent changes (e.g., temporary structures), and/or a periodicity of the changes. These changes can have varying levels of impact (e.g., a high impact or a low impact) to the physical entities. For example, a change in weather of the environment (e.g., when a temperature drops below 32 degrees Fahrenheit) may have a smaller impact (e.g., a low impact) on visibility and vision-based applications that rely on a digital twin. However, the same change in weather can have a greater impact (e.g., a high impact) on road safety applications that relay on the digital twin models.

Digital twins of physical entities (e.g., uDTs) along with digital twins of the environment (e.g., eDTs) of the physical entities as well as digital twins of the systems (e.g., oDTs) of the physical entities can be used to determine whether any updates (e.g., changes in a route of travel for a physical entity in the form of a vehicle) are needed for any of the physical entities and any of their associated digital twins due to changes within the environment. Currently, digital twin systems do not take into account the nature (e.g., characteristics) and impact of changes in the real-world environment for determining the necessity of updates and the manner of updates (e.g., modifications) for the physical entities and their associated digital twins. Not determining the nature (e.g., characteristics) and impact of changes in the real-world environment before triggering an update (e.g., a modification) of one or more digital twins can result in a large computational overhead (e.g., at any of the devices deployed at a central server that are tracking changes or propagating changes to the digital twins), a large communication overhead (e.g., for any of the UEs that are tracking changes in the real-world environment), and a large time-complexity of updating recurrent changes (e.g., that have a high impact on one or more applications and services).

As such, improved systems and techniques for real-time extrapolation and interactions of digital twin-based models and applications that take into account the nature (e.g., characteristics) and impact of changes in the real-world environment of the associated physical entities can be beneficial.

In some aspects of the present disclosure, systems, apparatuses, methods (also referred to as processes), and computer-readable media (collectively referred to herein as “systems and techniques”) are described herein for real-time extrapolation and interactions of digital twin-based models and applications.

Various aspects relate generally to wireless communications. Some aspects more specifically relate to systems and techniques that provide solutions that take into account the nature (e.g., characteristics, such as temporary, permanent, recurrent, non-recurrent, and/or a periodicity) and impact (e.g., high impact or low impact) of changes in a real-world environment of physical entities before triggering an update (e.g., a modification) to one or more associated digital twins due to the changes.

In one or more examples, during operation of the systems and techniques, once a change has been detected within a digital twin's environment (e.g., within an area of interest), tracking elements may be determined. In some examples, the tracking elements may include, but are not limited to, an estimate of a target area (e.g., which can be smaller than the area of interest), an estimate of an impact of the change to one or more particular applications, and an estimate of the nature (e.g., characteristics) of the change. If the change is determined to be a temporary change and has enough impact (e.g., a high impact), one or more smaller digital twin models relevant to the target area may be generated. If the change is determined to be a permanent change and has enough impact (e.g., a high impact), one or more existing digital twin models relevant in the area of interest may be modified (e.g., updated).

In some examples, during operation of the systems and techniques, a UE can transmit a digital twin interaction request to a network entity (e.g., including a machine learning server) and, in response, can receive a set of parameters from the network entity. The UE can then transmit a set of data elements (e.g., including visual data, geospatial data, radio frequency data, and/or other types of relevant data) to the network entity and, in response, can receive the output of a machine learning server (e.g., a server configured for machine learning) of the network entity. In one or more embodiments, a digital twin model may be determined (e.g., selected, created, obtained, etc.) based on an intended application.

In one or more examples, during operation of the systems and techniques for wireless communications, a network entity may determine one or more tracking elements based on detection of a change within an area of interest in a real-world environment of a UE, such as a vehicle. In some examples, the one or more tracking elements may include estimates of an impact of the change to one or more applications in the area of interest and one or more characteristics of the change. The network entity may determine, based on the impact of the change and the one or more characteristics of the change, whether to determine (e.g., select, create, obtain, etc.) one or more digital twin models for a target area within the area of interest or to modify one or more existing digital twin models for the area of interest.

In some examples, the one or more tracking elements may further include the target area, where the target area may be smaller in size than the area of interest. In one or more examples, the network entity may receive from the UE a set of data elements associated with the area of interest. In some examples, the set of data elements may include visual data, geospatial data, and/or radio frequency (RF) data. In one or more examples, the determination of the one or more tracking elements may be based on the set of data elements. In some examples, the one or more characteristics of the change may be a temporary change, a permanent change, a recurrent change, a non-recurrent change, and/or a periodic change (having a particular periodicity). In one or more examples, the impact of the change may be a first impact or a second impact, where the first impact may be a higher impact than the second impact. In one or more examples, the one or more digital twin models may be determined (e.g., selected, created, obtained, etc.) for the target area based on the one or more characteristics of the change being the temporary change and the impact of the change being the first impact. In some examples, the one or more existing digital twin models for the area of interest may be modified based on the one or more characteristics of the change being the permanent change and based on the impact of the change being the first impact. In one or more examples, the one or more digital twin models may be determined (e.g., selected, created, obtained, etc.) based on the one or more applications. In some examples, the network entity may include a server configured to perform machine learning. In one or more examples, the UE may be a vehicle. In some examples, the one or more digital twin models may include a virtual model of the UE, a virtual model of the environment, and/or a virtual model of a system comprising the UE.

In one or more examples, during operation of the systems and techniques for wireless communications, UE (e.g., a vehicle) may transmit a digital twin interaction request to a network entity based on detection of a change in an area of interest in a real-world environment of the UE. The UE may receive a set of parameters from the network entity, based the network entity receiving the digital twin interaction request. The UE may transmit a set of data elements to the network entity based on the set of parameters. The UE may receive from the network entity an output of a server configured for machine learning, based on the set of parameters and the set of data elements.

Particular aspects of the subject matter described in this disclosure can be implemented to realize one or more of the following potential advantages. In some examples, the systems and techniques, by identifying the nature (e.g., characteristics) and impact of the detected changes in the real-world environment of a physical entity before triggering an update of one or more digital twins, can avoid a large computational overhead at any of the devices deployed at a central server that are tracking changes or propagating changes to the digital twins, avoid a large communication overhead for any of the UEs that are tracking changes in the real-world environment, and minimize a time-complexity of updating recurrent changes that have a high impact on one or more applications and services. Minimizing the time-complexity of updating the recurrent changes can allow for a minimization of delays in adapting model parameters (e.g., hyperparameters that aid in the selection of ML models for inference) to their new optical values, and for a minimization of delays in adapting device configurations (e.g., range and field of view of sensing devices) to their new optimal values.

Additional aspects of the present disclosure are described in more detail below.

As used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently.

As used herein, the terms “user equipment” (UE) and “network entity” are not intended to be specific or otherwise limited to any particular radio access technology (RAT), unless otherwise noted. In general, a UE may be any wireless communication device (e.g., a mobile phone, router, tablet computer, laptop computer, and/or tracking device, etc.), wearable (e.g., smartwatch, smart-glasses, wearable ring, and/or an extended reality (XR) device such as a virtual reality (VR) headset, an augmented reality (AR) headset or glasses, or a mixed reality (MR) headset), vehicle (e.g., automobile, motorcycle, bicycle, etc.), aircraft (e.g., an airplane, jet, unmanned aerial vehicle (UAV) or drone, helicopter, airship, glider, etc.), and/or Internet of Things (IoT) device, etc., used by a user to communicate over a wireless communications network. A UE may be mobile or may (e.g., at certain times) be stationary, and may communicate with a radio access network (RAN). As used herein, the term “UE” may be referred to interchangeably as an “access terminal” or “AT,” a “client device,” a “wireless device,” a “subscriber device,” a “subscriber terminal,” a “subscriber station,” a “user terminal” or “UT,” a “mobile device,” a “mobile terminal,” a “mobile station,” or variations thereof. Generally, UEs can communicate with a core network via a RAN, and through the core network the UEs can be connected with external networks such as the Internet and with other UEs. Of course, other mechanisms of connecting to the core network and/or the Internet are also possible for the UEs, such as over wired access networks, wireless local area network (WLAN) networks (e.g., based on IEEE 802.11 communication standards, etc.), and so on.

A network entity can be implemented in an aggregated or monolithic base station architecture, or alternatively, in a disaggregated base station architecture, and may include one or more of a central unit (CU), a distributed unit (DU), a radio unit (RU), a Near-Real Time (Near-RT) RAN Intelligent Controller (RIC), or a Non-Real Time (Non-RT) RIC. A base station (e.g., with an aggregated/monolithic base station architecture or disaggregated base station architecture) may operate according to one of several RATs in communication with UEs depending on the network in which it is deployed, and may be alternatively referred to as an access point (AP), a network node, a NodeB (NB), an evolved NodeB (eNB), a next generation eNB (ng-eNB), a New Radio (NR) Node B (also referred to as a gNB or gNodeB), etc. A base station may be used primarily to support wireless access by UEs, including supporting data, voice, and/or signaling connections for the supported UEs. In some systems, a base station may provide edge node signaling functions while in other systems it may provide additional control and/or network management functions. A communication link through which UEs can send signals to a base station is called an uplink (UL) channel (e.g., a reverse traffic channel, a reverse control channel, an access channel, etc.). A communication link through which the base station can send signals to UEs is called a downlink (DL) or forward link channel (e.g., a paging channel, a control channel, a broadcast channel, or a forward traffic channel, etc.). The term traffic channel (TCH), as used herein, can refer to either an uplink, reverse or downlink, and/or a forward traffic channel.

The term “network entity” or “base station” (e.g., with an aggregated/monolithic base station architecture or disaggregated base station architecture) may refer to a single physical transmit receive point (TRP) or to multiple physical TRPs that may or may not be co-located. For example, where the term “network entity” or “base station” refers to a single physical TRP, the physical TRP may be an antenna of the base station corresponding to a cell (or several cell sectors) of the base station. Where the term “network entity” or “base station” refers to multiple co-located physical TRPs, the physical TRPs may be an array of antennas (e.g., as in a multiple-input multiple-output (MIMO) system or where the base station employs beamforming) of the base station. Where the term “base station” refers to multiple non-co-located physical TRPs, the physical TRPs may be a distributed antenna system (DAS) (e.g., a network of spatially separated antennas connected to a common source via a transport medium) or a remote radio head (RRH) (e.g., a remote base station connected to a serving base station). Alternatively, the non-co-located physical TRPs may be the serving base station receiving the measurement report from the UE and a neighbor base station whose reference radio frequency (RF) signals (e.g., or simply “reference signals”) the UE is measuring. Because a TRP is the point from which a base station transmits and receives wireless signals, as used herein, references to transmission from or reception at a base station are to be understood as referring to a particular TRP of the base station.

In some implementations that support positioning of UEs, a network entity or base station may not support wireless access by UEs (e.g., may not support data, voice, and/or signaling connections for UEs), but may instead transmit reference signals to UEs to be measured by the UEs, and/or may receive and measure signals transmitted by the UEs. Such a base station may be referred to as a positioning beacon (e.g., when transmitting signals to UEs) and/or as a location measurement unit (e.g., when receiving and measuring signals from UEs).

As described herein, a node (which may be referred to as a node, a network node, a network entity, or a wireless node) may include, be, or be included in (e.g., be a component of) a base station (e.g., any base station described herein), a UE (e.g., any UE described herein), a network controller, an apparatus, a device, a computing system, an integrated access and backhauling (IAB) node, a distributed unit (DU), a central unit (CU), a remote/radio unit (RU) (which may also be referred to as a remote radio unit (RRU)), and/or another processing entity configured to perform any of the techniques described herein. For example, a network node may be a UE. As another example, a network node may be a base station or network entity. As another example, a first network node may be configured to communicate with a second network node or a third network node. In one aspect of this example, the first network node may be a UE, the second network node may be a base station, and the third network node may be a UE. In another aspect of this example, the first network node may be a UE, the second network node may be a base station, and the third network node may be a base station. In yet other aspects of this example, the first, second, and third network nodes may be different relative to these examples. Similarly, reference to a UE, base station, apparatus, device, computing system, or the like may include disclosure of the UE, base station, apparatus, device, computing system, or the like being a network node. For example, disclosure that a UE is configured to receive information from a base station also discloses that a first network node is configured to receive information from a second network node. Consistent with this disclosure, once a specific example is broadened in accordance with this disclosure (e.g., a UE is configured to receive information from a base station also discloses that a first network node is configured to receive information from a second network node), the broader example of the narrower example may be interpreted in the reverse, but in a broad open-ended way. In the example above where a UE is configured to receive information from a base station also discloses that a first network node is configured to receive information from a second network node, the first network node may refer to a first UE, a first base station, a first apparatus, a first device, a first computing system, a first set of one or more one or more components, a first processing entity, or the like configured to receive the information; and the second network node may refer to a second UE, a second base station, a second apparatus, a second device, a second computing system, a second set of one or more components, a second processing entity, or the like.

As described herein, communication of information (e.g., any information, signal, or the like) may be described in various aspects using different terminology. Disclosure of one communication term includes disclosure of other communication terms. For example, a first network node may be described as being configured to transmit information to a second network node. In this example and consistent with this disclosure, disclosure that the first network node is configured to transmit information to the second network node includes disclosure that the first network node is configured to provide, send, output, communicate, or transmit information to the second network node. Similarly, in this example and consistent with this disclosure, disclosure that the first network node is configured to transmit information to the second network node includes disclosure that the second network node is configured to receive, obtain, or decode the information that is provided, sent, output, communicated, or transmitted by the first network node.

An RF signal comprises an electromagnetic wave of a given frequency that transports information through the space between a transmitter and a receiver. As used herein, a transmitter may transmit a single “RF signal” or multiple “RF signals” to a receiver. However, the receiver may receive multiple “RF signals” corresponding to each transmitted RF signal due to the propagation characteristics of RF signals through multipath channels. The same transmitted RF signal on different paths between the transmitter and receiver may be referred to as a “multipath” RF signal. As used herein, an RF signal may also be referred to as a “wireless signal” or simply a “signal” where it is clear from the context that the term “signal” refers to a wireless signal or an RF signal.

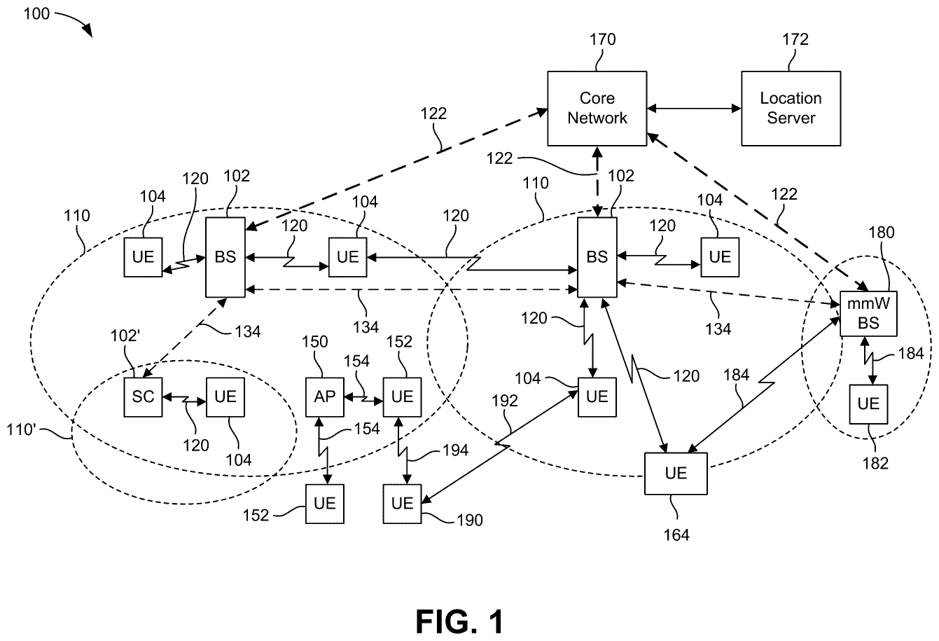

Various aspects of the systems and techniques described herein will be discussed below with respect to the figures. According to various aspects, FIG. 1 illustrates an example of a wireless communications system 100. The wireless communications system 100 (e.g., which may also be referred to as a wireless wide area network (WWAN)) can include various base stations 102 and various UEs 104. In some aspects, the base stations 102 may also be referred to as “network entities” or “network nodes.” One or more of the base stations 102 can be implemented in an aggregated or monolithic base station architecture. Additionally, or alternatively, one or more of the base stations 102 can be implemented in a disaggregated base station architecture, and may include one or more of a central unit (CU), a distributed unit (DU), a radio unit (RU), a Near-Real Time (Near-RT) RAN Intelligent Controller (RIC), or a Non-Real Time (Non-RT) RIC. The base stations 102 can include macro cell base stations (e.g., high power cellular base stations) and/or small cell base stations (e.g., low power cellular base stations). In an aspect, the macro cell base station may include eNBs and/or ng-eNBs where the wireless communications system 100 corresponds to a long-term evolution (LTE) network, or gNBs where the wireless communications system 100 corresponds to a NR network, or a combination of both, and the small cell base stations may include femtocells, picocells, microcells, etc.

The base stations 102 may collectively form a RAN and interface with a core network 170 (e.g., an evolved packet core (EPC) or a 5G core (5GC)) through backhaul links 122, and through the core network 170 to one or more location servers 172 (e.g., which may be part of core network 170 or may be external to core network 170). In addition to other functions, the base stations 102 may perform functions that relate to one or more of transferring user data, radio channel ciphering and deciphering, integrity protection, header compression, mobility control functions (e.g., handover, dual connectivity), inter-cell interference coordination, connection setup and release, load balancing, distribution for non-access stratum (NAS) messages, NAS node selection, synchronization, RAN sharing, multimedia broadcast multicast service (MBMS), subscriber and equipment trace, RAN information management (RIM), paging, positioning, and delivery of warning messages. The base stations 102 may communicate with each other directly or indirectly (e.g., through the EPC or 5GC) over backhaul links 134, which may be wired and/or wireless.

The base stations 102 may wirelessly communicate with the UEs 104. Each of the base stations 102 may provide communication coverage for a respective geographic coverage area 110. In an aspect, one or more cells may be supported by a base station 102 in each coverage area 110. A “cell” is a logical communication entity used for communication with a base station (e.g., over some frequency resource, referred to as a carrier frequency, component carrier, carrier, band, or the like), and may be associated with an identifier (e.g., a physical cell identifier (PCI), a virtual cell identifier (VCI), a cell global identifier (CGI)) for distinguishing cells operating via the same or a different carrier frequency. In some cases, different cells may be configured according to different protocol types (e.g., machine-type communication (MTC), narrowband IoT (NB-IoT), enhanced mobile broadband (eMBB), or others) that may provide access for different types of UEs. Because a cell is supported by a specific base station, the term “cell” may refer to either or both of the logical communication entity and the base station that supports it, depending on the context. In addition, because a TRP is typically the physical transmission point of a cell, the terms “cell” and “TRP” may be used interchangeably. In some cases, the term “cell” may also refer to a geographic coverage area of a base station (e.g., a sector), insofar as a carrier frequency can be detected and used for communication within some portion of geographic coverage areas 110.

While neighboring macro cell base station 102 geographic coverage areas 110 may partially overlap (e.g., in a handover region), some of the geographic coverage areas 1 10 may be substantially overlapped by a larger geographic coverage area 110. For example, a small cell base station 102′ may have a coverage area 110′ that substantially overlaps with the coverage area 110 of one or more macro cell base stations 102. A network that includes both small cell and macro cell base stations may be known as a heterogeneous network. A heterogeneous network may also include home eNBs (HeNBs), which may provide service to a restricted group known as a closed subscriber group (CSG).

The communication links 120 between the base stations 102 and the UEs 104 may include uplink (e.g., also referred to as reverse link) transmissions from a UE 104 to a base station 102 and/or downlink (e.g., also referred to as forward link) transmissions from a base station 102 to a UE 104. The communication links 120 may use MIMO antenna technology, including spatial multiplexing, beamforming, and/or transmit diversity. The communication links 120 may be provided using one or more carrier frequencies. Allocation of carriers may be asymmetric with respect to downlink and uplink (e.g., a greater or lesser quantity of carriers may be allocated for downlink than for uplink).

Beamforming, which may also be referred to as spatial filtering, directional transmission, or directional reception, is a signal processing technique that may be used at a transmitting device or a receiving device (e.g., one or more of the base stations 102, UEs 104, etc.) to shape or steer an antenna beam (e.g., a transmit beam, a receive beam) along a spatial path between the transmitting device and the receiving device. Beamforming may be implemented based on combining the signals communicated via antenna elements of an antenna array such that some signals propagating at particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

A transmitting device and/or a receiving device (e.g., such as one or more of base stations 102 and/or UEs 104) may use beam sweeping techniques as part of beam forming operations. For example, a base station 102 (e.g., or other transmitting device) may use multiple antennas or antenna arrays (e.g., antenna panels) to conduct beamforming operations for directional communications with a UE 104 (e.g., or other receiving device). Some signals (e.g., synchronization signals, reference signals, beam selection signals, or other control signals) may be transmitted by base station 102 (or other transmitting device) multiple times in different directions. For example, the base station 102 may transmit a signal according to different beamforming weight sets associated with different directions of transmission. Transmissions in different beam directions may be used to identify (e.g., by a transmitting device, such as a base station 102, or by a receiving device, such as a UE 104) a beam direction for later transmission or reception by the base station 102.

Some signals, such as data signals associated with a particular receiving device, may be transmitted by a base station 102 in a single beam direction (e.g., a direction associated with the receiving device, such as a UE 104). In some examples, the beam direction associated with transmissions along a single beam direction may be determined based on a signal that was transmitted in one or more beam directions. For example, a UE 104 may receive one or more of the signals transmitted by the base station 102 in different directions and may report to the base station 104 an indication of the signal that the UE 104 received with a highest signal quality or an otherwise acceptable signal quality.

In some examples, transmissions by a device (e.g., by a base station 102 or a UE 104) may be performed using multiple beam directions, and the device may use a combination of digital precoding or radio frequency beamforming to generate a combined beam for transmission (e.g., from a base station 102 to a UE 104, from a transmitting device to a receiving device, etc.). The UE 104 may report feedback that indicates precoding weights for one or more beam directions, and the feedback may correspond to a configured number of beams across a system bandwidth or one or more sub-bands. The base station 102 may transmit a reference signal (e.g., a cell-specific reference signal (CRS), a channel state information reference signal (CSI-RS), etc.), which may be precoded or unprecoded. The UE 104 may provide feedback for beam selection, which may be a precoding matrix indicator (PMI) or codebook-based feedback (e.g., a multi-panel type codebook, a linear combination type codebook, a port selection type codebook). Although these techniques are described with reference to signals transmitted in one or more directions by a base station 102, a UE 104 may employ similar techniques for transmitting signals multiple times in different directions (e.g., for identifying a beam direction for subsequent transmission or reception by the UE 104) or for transmitting a signal in a single direction (e.g., for transmitting data to a receiving device).

A receiving device (e.g., a UE 104) may try multiple receive configurations (e.g., directional listening) when receiving various signals from the base station 102, such as synchronization signals, reference signals, beam selection signals, or other control signals. For example, a receiving device may try multiple receive directions by receiving via different antenna subarrays, by processing received signals according to different antenna subarrays, by receiving according to different receive beamforming weight sets (e.g., different directional listening weight sets) applied to signals received at multiple antenna elements of an antenna array, or by processing received signals according to different receive beamforming weight sets applied to signals received at multiple antenna elements of an antenna array, any of which may be referred to as “listening” according to different receive configurations or receive directions. In some examples, a receiving device may use a single receive configuration to receive along a single beam direction (e.g., when receiving a data signal). The single receive configuration may be aligned in a beam direction determined based on listening according to different receive configuration directions (e.g., a beam direction determined to have a highest signal strength, highest signal-to-noise ratio (SNR), or otherwise acceptable signal quality based on listening according to multiple beam directions).

The wireless communications system 100 may further include a WLAN AP 150 in communication with WLAN stations (STAs) 152 via communication links 154 in an unlicensed frequency spectrum (e.g., 5 Gigahertz (GHz)). When communicating in an unlicensed frequency spectrum, the WLAN STAs 152 and/or the WLAN AP 150 may perform a clear channel assessment (CCA) or listen before talk (LBT) procedure prior to communicating in order to determine whether the channel is available. In some examples, the wireless communications system 100 can include devices (e.g., UEs, etc.) that communicate with one or more UEs 104, base stations 102, APs 150, etc., utilizing the ultra-wideband (UWB) spectrum. The UWB spectrum can range from 3.1 to 10.5 GHz.

The small cell base station 102′ may operate in a licensed and/or an unlicensed frequency spectrum. When operating in an unlicensed frequency spectrum, the small cell base station 102′ may employ LTE or NR technology and use the same 5 GHz unlicensed frequency spectrum as used by the WLAN AP 150. The small cell base station 102′, employing LTE and/or 5G in an unlicensed frequency spectrum, may boost coverage to and/or increase capacity of the access network. NR in unlicensed spectrum may be referred to as NR-U. LTE in an unlicensed spectrum may be referred to as LTE-U, licensed assisted access (LAA), or MulteFire.

The wireless communications system 100 may further include a millimeter wave (mmW) base station 180 that may operate in mmW frequencies and/or near mmW frequencies in communication with a UE 182. The mmW base station 180 may be implemented in an aggregated or monolithic base station architecture, or alternatively, in a disaggregated base station architecture (e.g., including one or more of a CU, a DU, a RU, a Near-RT RIC, or a Non-RT RIC). Extremely high frequency (EHF) is part of the RF in the electromagnetic spectrum. EHF has a range of 30 GHz to 300 GHz and a wavelength between 1 millimeter and 10 millimeters. Radio waves in this band may be referred to as a millimeter wave. Near mmW may extend down to a frequency of 3 GHz with a wavelength of 100 millimeters. The super high frequency (SHF) band extends between 3 GHz and 30 GHz, also referred to as centimeter wave. Communications using the mmW and/or near mmW radio frequency band have high path loss and a relatively short range. The mmW base station 180 and the UE 182 may utilize beamforming (e.g., transmit and/or receive) over an mmW communication link 184 to compensate for the extremely high path loss and short range. Further, it will be appreciated that in alternative configurations, one or more base stations 102 may also transmit using mmW or near mmW and beamforming. Accordingly, it will be appreciated that the foregoing illustrations are merely examples and should not be construed to limit the various aspects disclosed herein.

In some aspects relating to 5G, the frequency spectrum in which wireless network nodes or entities (e.g., base stations 102/180, UEs 104/182) operate is divided into multiple frequency ranges, FRI (e.g., from 450 to 6,000 Megahertz (MHz)), FR2 (e.g., from 24,250 to 52,600 MHz), FR3 (e.g., above 52,600 MHz), and FR4 (e.g., between FR1 and FR2). In a multi-carrier system, such as 5G, one of the carrier frequencies is referred to as the “primary carrier” or “anchor carrier” or “primary serving cell” or “PCell,” and the remaining carrier frequencies are referred to as “secondary carriers” or “secondary serving cells” or “SCells.” In carrier aggregation, the anchor carrier is the carrier operating on the primary frequency (e.g., FR1) utilized by a UE 104/182 and the cell in which the UE 104/182 either performs the initial radio resource control (RRC) connection establishment procedure or initiates the RRC connection re-establishment procedure. The primary carrier carries all common and UE-specific control channels and may be a carrier in a licensed frequency (however, this is not always the case). A secondary carrier is a carrier operating on a second frequency (e.g., FR2) that may be configured once the RRC connection is established between the UE 104 and the anchor carrier and that may be used to provide additional radio resources. In some cases, the secondary carrier may be a carrier in an unlicensed frequency. The secondary carrier may contain only necessary signaling information and signals, for example, those that are UE-specific may not be present in the secondary carrier, since both primary uplink and downlink carriers are typically UE-specific. This means that different UEs 104/182 in a cell may have different downlink primary carriers. The same is true for the uplink primary carriers. The network is able to change the primary carrier of any UE 104/182 at any time. This is done, for example, to balance the load on different carriers. Because a “serving cell” (e.g., whether a PCell or an SCell) corresponds to a carrier frequency and/or component carrier over which some base station is communicating, the term “cell,” “serving cell,” “component carrier,” “carrier frequency,” and the like can be used interchangeably.

For example, still referring to FIG. 1, one of the frequencies utilized by the macro cell base stations 102 may be an anchor carrier (or “PCell”) and other frequencies utilized by the macro cell base stations 102 and/or the mmW base station 180 may be secondary carriers (“SCells”). In carrier aggregation, the base stations 102 and/or the UEs 104 may use spectrum up to Y MHz (e.g., 5, 10, 15, 20, 100 MHz) bandwidth per carrier up to a total of Yx MHz (e.g., x component carriers) for transmission in each direction. The component carriers may or may not be adjacent to each other on the frequency spectrum. Allocation of carriers may be asymmetric with respect to the downlink and uplink (e.g., a greater or lesser quantity of carriers may be allocated for downlink than for uplink). The simultaneous transmission and/or reception of multiple carriers enables the UE 104/182 to significantly increase its data transmission and/or reception rates. For example, two 20 MHz aggregated carriers in a multi-carrier system would theoretically lead to a two-fold increase in data rate (e.g., 40 MHz), compared to that attained by a single 20 MHz carrier.

In order to operate on multiple carrier frequencies, a base station 102 and/or a UE 104 can be equipped with multiple receivers and/or transmitters. For example, a UE 104 may have two receivers, “Receiver 1” and “Receiver 2,” where “Receiver 1” is a multi-band receiver that can be tuned to band (e.g., carrier frequency) ‘X’ or band ‘Y,’ and “Receiver 2” is a one-band receiver tunable to band ‘Z’ only. In this example, if the UE 104 is being served in band ‘X,’ band ‘X’ would be referred to as the PCell or the active carrier frequency, and “Receiver 1” would need to tune from band ‘X’ to band ‘Y’ (e.g., an SCell) in order to measure band ‘Y’ (and vice versa). In contrast, whether the UE 104 is being served in band ‘X’ or band ‘Y,’ because of the separate “Receiver 2,” the UE 104 can measure band ‘Z’ without interrupting the service on band ‘X’ or band ‘Y.’

The wireless communications system 100 may further include a UE 164 that may communicate with a macro cell base station 102 over a communication link 120 and/or the mmW base station 180 over an mmW communication link 184. For example, the macro cell base station 102 may support a PCell and one or more SCells for the UE 164 and the mmW base station 180 may support one or more SCells for the UE 164.

The wireless communications system 100 may further include one or more UEs, such as UE 190, that connects indirectly to one or more communication networks via one or more device-to-device (D2D) peer-to-peer (P2P) links (e.g., referred to as “sidelinks”). In the example of FIG. 1, UE 190 has a D2D P2P link 192 with one of the UEs 104 connected to one of the base stations 102 (e.g., through which UE 190 may indirectly obtain cellular connectivity) and a D2D P2P link 194 with WLAN STA 152 connected to the WLAN AP 150 (e.g., through which UE 190 may indirectly obtain WLAN-based Internet connectivity). In an example, the D2D P2P links 192 and 194 may be supported with any well-known D2D RAT, such as LTE Direct (LTE-D), Wi-Fi Direct (Wi-Fi-D), Bluetooth®, and so on.

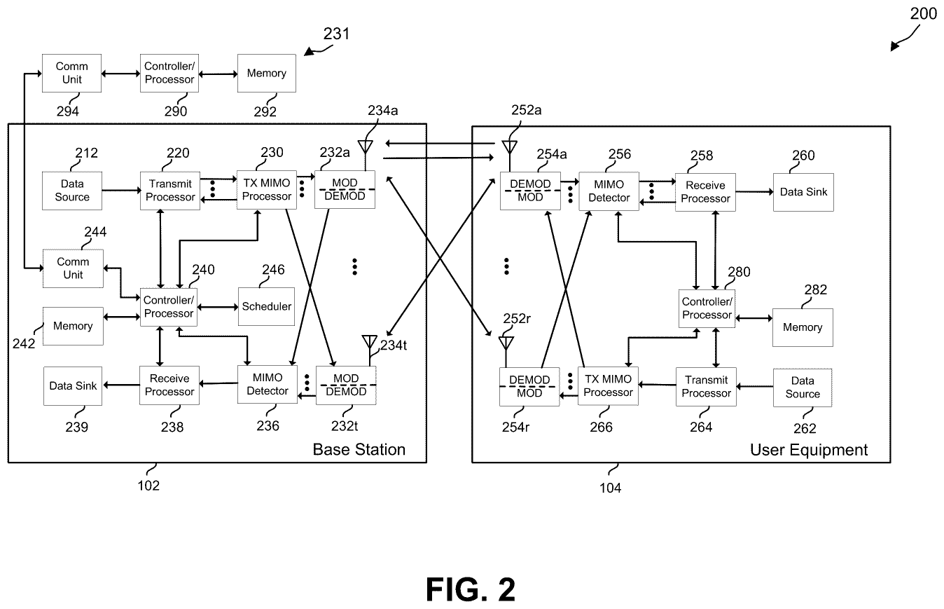

FIG. 2 illustrates a block diagram of an example architecture 200 of a base station 102 and a UE 104 that enables transmission and processing of signals exchanged between the UE and the base station, in accordance with some aspects of the present disclosure. Example architecture 200 includes components of a base station 102 and a UE 104, which may be one of the base stations 102 and one of the UEs 104 illustrated in FIG. 1. Base station 102 may be equipped with T antennas 234a through 234t, and UE 104 may be equipped with R antennas 252a through 252r, where in general T≥1 and R≥1.

At base station 102, a transmit processor 220 may receive data from a data source 212 for one or more UEs, select one or more modulation and coding schemes (MCS) for each UE based on channel quality indicators (CQIs) received from the UE, process (e.g., encode and modulate) the data for each UE based on the MCS(s) selected for the UE, and provide data symbols for all UEs. Transmit processor 220 may also process system information (e.g., for semi-static resource partitioning information (SRPI) and/or the like) and control information (e.g., CQI requests, grants, upper layer signaling, and/or the like) and provide overhead symbols and control symbols. Transmit processor 220 may also generate reference symbols for reference signals (e.g., the cell-specific reference signal (CRS)) and synchronization signals (e.g., the primary synchronization signal (PSS) and secondary synchronization signal (SSS)). A transmit (TX) multiple-input multiple-output (MIMO) processor 230 may perform spatial processing (e.g., precoding) on the data symbols, the control symbols, the overhead symbols, and/or the reference symbols, if applicable, and may provide T output symbol streams to T modulators (MODs) 232a through 232t. The modulators 232a through 232t are shown as a combined modulator-demodulator (MOD-DEMOD). In some cases, the modulators and demodulators can be separate components. Each modulator of the modulators 232a to 232t may process a respective output symbol stream (e.g., for an orthogonal frequency-division multiplexing (OFDM) scheme and/or the like) to obtain an output sample stream. Each modulator of the modulators 232a to 232t may further process (e.g., convert to analog, amplify, filter, and upconvert) the output sample stream to obtain a downlink signal. T downlink signals may be transmitted from modulators 232a to 232t via T antennas 234a through 234t, respectively. According to certain aspects described in more detail below, the synchronization signals can be generated with location encoding to convey additional information.

At UE 104, antennas 252a through 252r may receive the downlink signals from base station 102 and/or other base stations and may provide received signals to one or more demodulators (DEMODs) 254a through 254r, respectively. The demodulators 254a through 254r are shown as a combined modulator-demodulator (MOD-DEMOD). In some cases, the modulators and demodulators can be separate components. Each demodulator of the demodulators 254a through 254r may condition (e.g., filter, amplify, downconvert, and digitize) a received signal to obtain input samples. Each demodulator of the demodulators 254a through 254r may further process the input samples (e.g., for OFDM and/or the like) to obtain received symbols. A MIMO detector 256 may obtain received symbols from all R demodulators 254a through 254r, perform MIMO detection on the received symbols if applicable, and provide detected symbols. A receive processor 258 may process (e.g., demodulate and decode) the detected symbols, provide decoded data for UE 104 to a data sink 260, and provide decoded control information and system information to a controller/processor 280. A channel processor may determine reference signal received power (RSRP), received signal strength indicator (RSSI), reference signal received quality (RSRQ), channel quality indicator (CQI), and/or the like.

On the uplink, at UE 104, a transmit processor 264 may receive and process data from a data source 262 and control information (e.g., for reports comprising RSRP, RSSI, RSRQ, CQI, and/or the like) from controller/processor 280. Transmit processor 264 may also generate reference symbols for one or more reference signals (e.g., based on a beta value or a set of beta values associated with the one or more reference signals). The symbols from transmit processor 264 may be precoded by a TX-MIMO processor 266, further processed by modulators 254a through 254r (e.g., for DFT-s-OFDM, CP-OFDM, and/or the like), and transmitted to base station 102. At base station 102, the uplink signals from UE 104 and other UEs may be received by antennas 234a through 234t, processed by demodulators 232a through 232t, detected by a MIMO detector 236 (e.g., if applicable), and further processed by a receive processor 238 to obtain decoded data and control information sent by UE 104. Receive processor 238 may provide the decoded data to a data sink 239 and the decoded control information to controller (e.g., processor) 240. Base station 102 may include communication unit 244 and communicate to a network controller 231 via communication unit 244. Network controller 231 may include communication unit 294, controller/processor 290, and memory 292.

In some aspects, one or more components of UE 104 may be included in a housing. Controller 240 of base station 102, controller/processor 280 of UE 104, and/or any other component(s) of FIG. 2 may perform one or more techniques associated with implicit UCI beta value determination for NR.

Memories 242 and 282 may store data and program codes for the base station 102 and the UE 104, respectively. A scheduler 246 may schedule UEs for data transmission on the downlink, uplink, and/or sidelink.

In some aspects, deployment of communication systems, such as 5G new radio (NR) systems, may be arranged in multiple manners with various components or constituent parts. In a 5G NR system, or network, a network node, a network entity, a mobility element of a network, a radio access network (RAN) node, a core network node, a network element, or a network equipment, such as a base station (BS), or one or more units (or one or more components) performing base station functionality, may be implemented in an aggregated or disaggregated architecture. For example, a BS (e.g., such as a Node B (NB), evolved NB (eNB), NR BS, 5G NB, access point (AP), a transmit receive point (TRP), or a cell, etc.) may be implemented as an aggregated base station (e.g., also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (e.g., such as one or more central or centralized units (CUs), one or more distributed units (DUs), or one or more radio units (RUS)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU and RU also can be implemented as virtual units, e.g., a virtual central unit (VCU), a virtual distributed unit (VDU), or a virtual radio unit (VRU).

Base station-type operation or network design may consider aggregation characteristics of base station functionality. For example, disaggregated base stations may be utilized in an integrated access backhaul (IAB) network, an open radio access network (O-RAN (e.g., such as the network configuration sponsored by the O-RAN Alliance)), or a virtualized radio access network (e.g., vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

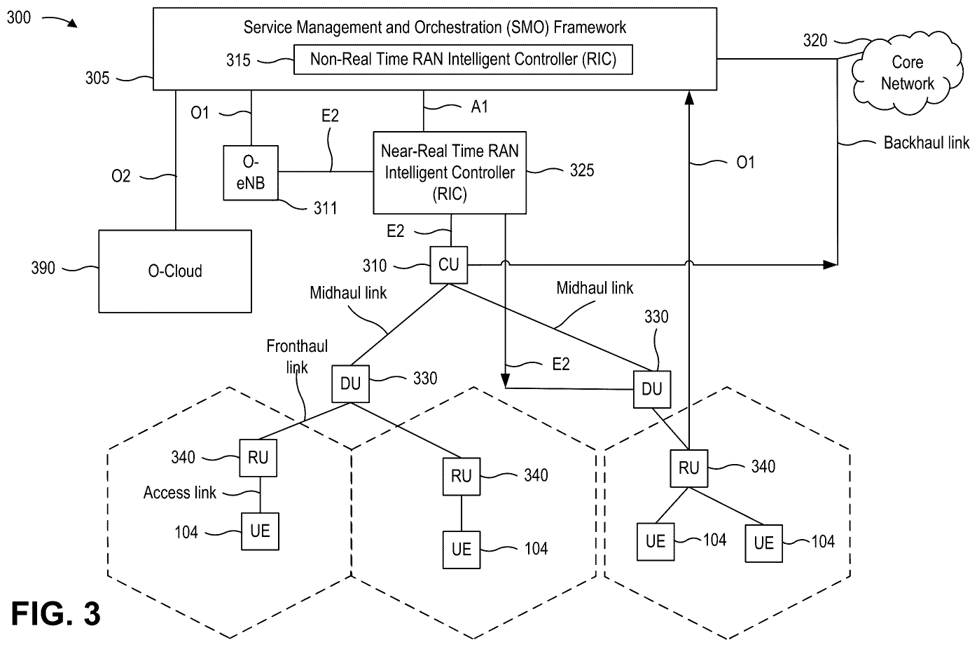

FIG. 3 is a diagram illustrating an example disaggregated base station 300 architecture. The disaggregated base station 300 architecture may include one or more central units (CUs) 310 that can communicate directly with a core network 320 via a backhaul link, or indirectly with the core network 320 through one or more disaggregated base station units (e.g., such as a Near-Real Time (Near-RT) RAN Intelligent Controller (RIC) 325 via an E2 link, or a Non-Real Time (Non-RT) RIC 315 associated with a Service Management and Orchestration (SMO) Framework 305, or both). A CU 310 may communicate with one or more distributed units (DUs) 330 via respective midhaul links, such as an FI interface. The DUs 330 may communicate with one or more radio units (RUs) 340 via respective fronthaul links. The RUs 340 may communicate with respective UEs 104 via one or more radio frequency (RF) access links. In some implementations, the UE 104 may be simultaneously served by multiple RUs 340.

Each of the units (e.g., the CUS 310, the DUs 330, the RUs 340, as well as the Near-RT RICs 325, the Non-RT RICs 315, and the SMO Framework 305) illustrated in FIG. 3 and/or described herein may include one or more interfaces or be coupled to one or more interfaces configured to receive or transmit signals, data, or information (e.g., collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or transmit signals over a wired transmission medium to one or more of the other units. Additionally, the units can include a wireless interface, which may include a receiver, a transmitter or transceiver (e.g., such as a radio frequency (RF) transceiver), configured to receive or transmit signals, or both, over a wireless transmission medium to one or more of the other units.

In some aspects, the CU 310 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 310. The CU 310 may be configured to handle user plane functionality (e.g., Central Unit-User Plane (CU-UP)), control plane functionality (e.g., Central Unit-Control Plane (CU-CP)), or a combination thereof. In some implementations, the CU 310 can be logically split into one or more CU-UP units and one or more CU-CP units. The CU-UP unit can communicate bidirectionally with the CU-CP unit via an interface, such as the E1 interface when implemented in an O-RAN configuration. The CU 310 can be implemented to communicate with the DU 330, as necessary, for network control and signaling.

The DU 330 may correspond to a logical unit that includes one or more base station functions to control the operation of one or more RUs 340. In some aspects, the DU 330 may host one or more of a radio link control (RLC) layer, a medium access control (MAC) layer, and one or more high physical (PHY) layers (e.g., such as modules for forward error correction (FEC) encoding and decoding, scrambling, modulation and demodulation, or the like) depending on a functional split, such as those defined by the 3rd Generation Partnership Project (3GPP). In some aspects, the DU 330 may further host one or more low PHY layers. Each layer (or module) can be implemented with an interface configured to communicate signals with other layers (and modules) hosted by the DU 330, or with the control functions hosted by the CU 310.

Lower-layer functionality can be implemented by one or more RUs 340. In some deployments, an RU 340, controlled by a DU 330, may correspond to a logical node that hosts RF processing functions, or low-PHY layer functions (e.g., such as performing fast Fourier transform (FFT), inverse FFT (iFFT), digital beamforming, physical random-access channel (PRACH) extraction and filtering, or the like), or both, based on the functional split, such as a lower layer functional split. In such an architecture, the RU(s) 340 can be implemented to handle over the air (OTA) communication with one or more UEs 104. In some implementations, real-time and non-real-time aspects of control and user plane communication with the RU(s) 340 can be controlled by the corresponding DU 330. In some scenarios, this configuration can enable the DU(s) 330 and the CU 310 to be implemented in a cloud-based RAN architecture, such as a vRAN architecture.

The SMO Framework 305 may be configured to support RAN deployment and provisioning of non-virtualized and virtualized network elements. For non-virtualized network elements, the SMO Framework 305 may be configured to support the deployment of dedicated physical resources for RAN coverage requirements which may be managed via an operations and maintenance interface (e.g., such as an O1 interface). For virtualized network elements, the SMO Framework 305 may be configured to interact with a cloud computing platform (e.g., such as an open cloud (O-Cloud) 390) to perform network element life cycle management (e.g., such as to instantiate virtualized network elements) via a cloud computing platform interface (e.g., such as an O2 interface). Such virtualized network elements can include, but are not limited to, CUs 310, DUs 330, RUs 340, and Near-RT RICs 325. In some implementations, the SMO Framework 305 can communicate with a hardware aspect of a 4G RAN, such as an open eNB (O-eNB) 311, via an O1 interface. Additionally, in some implementations, the SMO Framework 305 can communicate directly with one or more RUs 340 via an O1 interface. The SMO Framework 305 also may include a Non-RT RIC 315 configured to support functionality of the SMO Framework 305.

The Non-RT RIC 315 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 325. The Non-RT RIC 315 may be coupled to or communicate with (e.g., such as via an Al interface) the Near-RT RIC 325. The Near-RT RIC 325 may be configured to include a logical function that enables near-real-time control and optimization of RAN elements and resources via data collection and actions over an interface (e.g., such as via an E2 interface) connecting one or more CUs 310, one or more DUs 330, or both, as well as an O-eNB, with the Near-RT RIC 325.

In some implementations, to generate AI/ML models to be deployed in the Near-RT RIC 325, the Non-RT RIC 315 may receive parameters or external enrichment information from external servers. Such information may be utilized by the Near-RT RIC 325 and may be received at the SMO Framework 305 or the Non-RT RIC 315 from non-network data sources or from network functions. In some examples, the Non-RT RIC 315 or the Near-RT RIC 325 may be configured to tune RAN behavior or performance. For example, the Non-RT RIC 315 may monitor long-term trends and patterns for performance and employ AI/ML models to perform corrective actions through the SMO Framework 305 (e.g., such as reconfiguration via O1) or via creation of RAN management policies (e.g., such as Al policies).

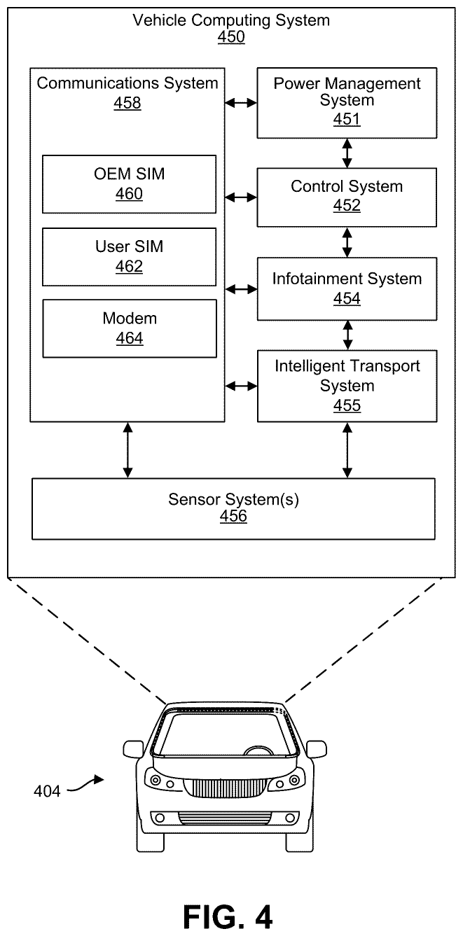

FIG. 4 is a block diagram illustrating an example vehicle computing system 450 of a vehicle 404. In some examples, the vehicle computing system 450 may be referred to as an on-board unit (OBU). The vehicle 404 is an example of a UE that may communicate with a network (e.g., an eNB, a gNB, a positioning beacon, a location measurement unit, and/or other network entity) over a Uu interface and with other UEs using V2X communications over a PC5 interface (or other device to device direct interface). As shown, the vehicle computing system 450 may include at least a power management system 451, a control system 452, an infotainment system 454, an intelligent transport system (ITS) 455, one or more sensor systems 456, and a communications system 458. In some cases, the vehicle computing system 450 may include or may be implemented using any type of processing device or system, such as one or more central processing units (CPUs), digital signal processors (DSPs), application specific integrated circuits (ASICs), field programmable gate arrays (FPGAs), application processors (APs), graphics processing units (GPUs), vision processing units (VPUs), Neural Network Signal Processors (NSPs), microcontrollers, dedicated hardware, any combination thereof, and/or other processing device or system.

The control system 452 may be configured to control one or more operations of the vehicle 404, the power management system 451, the computing system 450, the infotainment system 454, the ITS 455, and/or one or more other systems of the vehicle 404 (e.g., a braking system, a steering system, a safety system other than the ITS 455, a cabin system, and/or other system). In some examples, the control system 452 may include one or more electronic control units (ECUs). An ECU may control one or more of the electrical systems or subsystems in a vehicle. Examples of specific ECUs that may be included as part of the control system 452 include an engine control module (ECM), a powertrain control module (PCM), a transmission control module (TCM), a brake control module (BCM), a central control module (CCM), a central timing module (CTM), among others. In some cases, the control system 452 may receive sensor signals from the one or more sensor systems 456 and may communicate with other systems of the vehicle computing system 450 to operate the vehicle 404.

The vehicle computing system 450 also includes a power management system 451. In some implementations, the power management system 451 may include a power management integrated circuit (PMIC), a standby battery, and/or other components. In some cases, other systems of the vehicle computing system 450 may include one or more PMICs, batteries, and/or other components. The power management system 451 may perform power management functions for the vehicle 404, such as managing a power supply for the computing system 450 and/or other parts of the vehicle. For example, the power management system 451 may provide a stable power supply in view of power fluctuations, such as based on starting an engine of the vehicle. In another example, the power management system 451 may perform thermal monitoring operations, such as by checking ambient and/or transistor junction temperatures. In another example, the power management system 451 may perform certain functions based on detecting a certain temperature level, such as causing a cooling system (e.g., one or more fans, an air conditioning system, etc.) to cool certain components of the vehicle computing system 450 (e.g., the control system 452, such as one or more ECUs), shutting down certain functionalities of the vehicle computing system 450 (e.g., limiting the infotainment system 454, such as by shutting off one or more displays, disconnecting from a wireless network, etc.), among other functions.

The vehicle computing system 450 further includes a communications system 458. The communications system 458 may include both software and hardware components for transmitting signals to and receiving signals from a network (e.g., a gNB or other network entity over a Uu interface) and/or from other UEs (e.g., to another vehicle or UE over a PC5 interface, WiFi interface, Bluetooth™ interface, and/or other wireless and/or wired interface). For example, the communications system 458 is configured to transmit and receive information wirelessly over any suitable wireless network (e.g., a 3G network, 4G network, 5G network, WiFi network, Bluetooth™ network, and/or other network). The communications system 458 includes various components or devices used to perform the wireless communication functionalities, including an original equipment manufacturer (OEM) subscriber identity module (referred to as a SIM or SIM card) 460, a user SIM 462, and a modem 464. While the vehicle computing system 450 is shown as having two SIMs and one modem, the computing system 450 may have any number of SIMs (e.g., one SIM or more than two SIMs) and any number of modems (e.g., one modem, two modems, or more than two modems) in some implementations.

A SIM is a device (e.g., an integrated circuit) that may securely store an international mobile subscriber identity (IMSI) number and a related key (e.g., an encryption-decryption key) of a particular subscriber or user. The IMSI and key may be used to identify and authenticate the subscriber on a particular UE. The OEM SIM 460 may be used by the communications system 458 for establishing a wireless connection for vehicle-based operations, such as for conducting emergency-calling (eCall) functions, communicating with a communications system of the vehicle manufacturer (e.g., for software updates, etc.), among other operations. The OEM SIM 460 may be used to support one or more services such as eCall for making emergency calls in the event of a car accident or other emergency. For instance, eCall may include a service that automatically dials an emergency number (e.g., “9-1-1” in the United States, “1-1-2” in Europe, etc.) in the event of a vehicle accident and communicates a location of the vehicle to the emergency services, such as a police department, fire department, etc.

The user SIM 462 may be used by the communications system 458 for performing wireless network access functions in order to support a user data connection (e.g., for conducting phone calls, messaging, Infotainment related services, among others). In some cases, a user device of a user may connect with the vehicle computing system 450 over an interface (e.g., over PC5, Bluetooth™, WiFi™, a universal serial bus (USB) port, and/or other wireless or wired interface). Once connected, the user device may transfer wireless network access functionality from the user device to communications system 458 the vehicle, in which case the user device may cease performance of the wireless network access functionality (e.g., during the period in which the communications system 458 is performing the wireless access functionality). The communications system 458 may begin interacting with a base station to perform one or more wireless communication operations, such as facilitating a phone call, transmitting and/or receiving data (e.g., messaging, video, audio, etc.), among other operations. In such cases, other components of the vehicle computing system 450 may be used to output data received by the communications system 458. For example, the infotainment system 454 (described below) may display video received by the communications system 458 on one or more displays and/or may output audio received by the communications system 458 using one or more speakers.

A modem is a device that modulates one or more carrier wave signals to encode digital information for transmission, and demodulates signals to decode the transmitted information. The modem 464 (and/or one or more other modems of the communications system 458) may be used for communication of data for the OEM SIM 460 and/or the user SIM 462. In some examples, the modem 464 may include a 4G (or LTE) modem and another modem (not shown) of the communications system 458 may include a 5G (or NR) modem. In some examples, the communications system 458 may include one or more Bluetooth™ modems (e.g., for Bluetooth™ Low Energy (BLE) or other type of Bluetooth communications), one or more WiFi™ modems (e.g., for DSRC communications and/or other WiFi communications), wideband modems (e.g., an ultra-wideband (UWB) modem), any combination thereof, and/or other types of modems.

In some cases, the modem 464 (and/or one or more other modems of the communications system 458) may be used for performing V2X communications (e.g., with other vehicles for V2V communications, with other devices for D2D communications, with infrastructure systems for V2I communications, with pedestrian UEs for V2P communications, etc.). In some examples, the communications system 458 may include a V2X modem used for performing V2X communications (e.g., sidelink communications over a PC5 interface), in which case the V2X modem may be separate from one or more modems used for wireless network access functions (e.g., for network communications over a network/Uu interface and/or sidelink communications other than V2X communications).

In some examples, the communications system 458 may be or may include a telematics control unit (TCU). In some implementations, the TCU may include a network access device (NAD) (also referred to in some cases as a network control unit or NCU). The NAD may include the modem 464, any other modem not shown in FIG. 4, the OEM SIM 460, the user SIM 462, and/or other components used for wireless communications. In some examples, the communications system 458 may include a Global Navigation Satellite System (GNSS). In some cases, the GNSS may be part of the one or more sensor systems 456, as described below. The GNSS may provide the ability for the vehicle computing system 450 to perform one or more location services, navigation services, and/or other services that may utilize GNSS functionality.

In some cases, the communications system 458 may further include one or more wireless interfaces (e.g., including one or more transceivers and one or more baseband processors for each wireless interface) for transmitting and receiving wireless communications, one or more wired interfaces (e.g., a serial interface such as a universal serial bus (USB) input, a lightening connector, and/or other wired interface) for performing communications over one or more hardwired connections, and/or other components that may allow the vehicle 404 to communicate with a network and/or other UEs.

The vehicle computing system 450 may also include an infotainment system 454 that may control content and one or more output devices of the vehicle 404 that may be used to output the content. The infotainment system 454 may also be referred to as an in-vehicle infotainment (IVI) system or an In-car entertainment (ICE) system. The content may include navigation content, media content (e.g., video content, music or other audio content, and/or other media content), among other content. The one or more output devices may include one or more graphical user interfaces, one or more displays, one or more speakers, one or more extended reality devices (e.g., a VR, AR, and/or MR headset), one or more haptic feedback devices (e.g., one or more devices configured to vibrate a seat, steering wheel, and/or other part of the vehicle 404), and/or other output device.

In some examples, the computing system 450 may include the intelligent transport system (ITS) 455. In some examples, the ITS 455 may be used for implementing V2X communications. For example, an ITS stack of the ITS 455 may generate V2X messages based on information from an application layer of the ITS. In some cases, the application layer may determine whether certain conditions have been met for generating messages for use by the ITS 455 and/or for generating messages that are to be sent to other vehicles (for V2V communications), to pedestrian UEs (for V2P communications), and/or to infrastructure systems (for V2I communications). In some cases, the communications system 458 and/or the ITS 455 may obtain car access network (CAN) information (e.g., from other components of the vehicle via a CAN bus). In some examples, the communications system 458 (e.g., a TCU NAD) may obtain the CAN information via the CAN bus and may send the CAN information to the ITS stack. The CAN information may include vehicle related information, such as a heading of the vehicle, speed of the vehicle, breaking information, among other information. The CAN information may be continuously or periodically (e.g., every 1 millisecond (ms), every 10 ms, or the like) provided to the ITS 455.

The conditions used to determine whether to generate messages may be determined using the CAN information based on safety-related applications and/or other applications, including applications related to road safety, traffic efficiency, infotainment, business, and/or other applications. In one illustrative example, ITS 455 may perform lane change assistance or negotiation. For instance, using the CAN information, the ITS 455 may determine that a driver of the vehicle 404 is attempting to change lanes from a current lane to an adjacent lane (e.g., based on a blinker being activated, based on the user veering or steering into an adjacent lane, etc.). Based on determining the vehicle 404 is attempting to change lanes, the ITS 455 may determine a lane-change condition has been met that is associated with a message to be sent to other vehicles that are nearby the vehicle in the adjacent lane. The ITS 455 may trigger the ITS stack to generate one or more messages for transmission to the other vehicles, which may be used to negotiate a lane change with the other vehicles. Other examples of applications include forward collision warning, automatic emergency breaking, lane departure warning, pedestrian avoidance or protection (e.g., when a pedestrian is detected near the vehicle 404, such as based on V2P communications with a UE of the user), traffic sign recognition, among others.

The ITS 455 may use any suitable protocol to generate messages (e.g., V2X messages). Examples of protocols that may be used by the ITS 455 include one or more Society of Automotive Engineering (SAE) standards, such as SAE J2735, SAE J2945, SAE J3161, and/or other standards, which are hereby incorporated by reference in their entirety and for all purposes.

A security layer of the ITS 455 may be used to securely sign messages from the ITS stack that are sent to and verified by other UEs configured for V2X communications, such as other vehicles, pedestrian UEs, and/or infrastructure systems. The security layer may also verify messages received from such other UEs. In some implementations, the signing and verification processes may be based on a security context of the vehicle. In some examples, the security context may include one or more encryption-decryption algorithms, a public and/or private key used to generate a signature using an encryption-decryption algorithm, and/or other information. For example, each ITS message generated by the ITS stack may be signed by the security layer. The signature may be derived using a public key and an encryption-decryption algorithm. A vehicle, pedestrian UE, and/or infrastructure system receiving a signed message may verify the signature to make sure the message is from an authorized vehicle. In some examples, the one or more encryption-decryption algorithms may include one or more symmetric encryption algorithms (e.g., advanced encryption standard (AES), data encryption standard (DES), and/or other symmetric encryption algorithm), one or more asymmetric encryption algorithms using public and private keys (e.g., Rivest-Shamir-Adleman (RSA) and/or other asymmetric encryption algorithm), and/or other encryption-decryption algorithm.

In some examples, the ITS 455 may determine certain operations (e.g., V2X-based operations) to perform based on messages received from other UEs. The operations may include safety-related and/or other operations, such as operations for road safety, traffic efficiency, infotainment, business, and/or other applications. In some examples, the operations may include causing the vehicle (e.g., the control system 452) to perform automatic functions, such as automatic breaking, automatic steering (e.g., to maintain a heading in a particular lane), automatic lane change negotiation with other vehicles, among other automatic functions. In one illustrative example, a message may be received by the communications system 458 from another vehicle (e.g., over a PC5 interface) indicating that the other vehicle is coming to a sudden stop. In response to receiving the message, the ITS 455 may generate a message or instruction and may send the message or instruction to the control system 452, which may cause the control system 452 to automatically break the vehicle 404 so that it comes to a stop before making impact with the other vehicle. In other illustrative examples, the operations may include triggering display of a message alerting a driver that another vehicle is in the lane next to the vehicle, a message alerting the driver to stop the vehicle, a message alerting the driver that a pedestrian is in an upcoming cross-walk, a message alerting the driver that a toll booth is within a certain distance (e.g., within 1 mile) of the vehicle, among others.

The computing system 450 further includes one or more sensor systems 456 (e.g., a first sensor system through an Nth sensor system, where N is a value equal to or greater than 0). When including multiple sensor systems, the sensor system(s) 456 may include different types of sensor systems that may be arranged on or in different parts the vehicle 404. The sensor system(s) 456 may include one or more camera sensor systems, Light Detection and Ranging (LIDAR) sensor systems, radio detection and ranging (RADAR) sensor systems, Electromagnetic Detection and Ranging (EmDAR) sensor systems, Sound Navigation and Ranging (SONAR) sensor systems, Sound Detection and Ranging (SODAR) sensor systems, Global Navigation Satellite System (GNSS) receiver systems (e.g., one or more Global Positioning System (GPS) receiver systems), accelerometers, gyroscopes, inertial measurement units (IMUs), infrared sensor systems, laser rangefinder systems, ultrasonic sensor systems, infrasonic sensor systems, microphones, any combination thereof, and/or other sensor systems. It should be understood that any number of sensors or sensor systems may be included as part of the computing system 450 of the vehicle 404.

While the vehicle computing system 450 is shown to include certain components and/or systems, one of ordinary skill will appreciate that the vehicle computing system 450 may include more or fewer components than those shown in FIG. 4. For example, the vehicle computing system 450 may also include one or more input devices and one or more output devices (not shown). In some implementations, the vehicle computing system 450 may also include (e.g., as part of or separate from the control system 452, the infotainment system 454, the communications system 458, and/or the sensor system(s) 456) at least one processor and at least one memory having computer-executable instructions that are executed by the at least one processor. The at least one processor is in communication with and/or electrically connected to (referred to as being “coupled to” or “communicatively coupled”) the at least one memory. The at least one processor may include, for example, one or more microcontrollers, one or more central processing units (CPUs), one or more field programmable gate arrays (FPGAs), one or more graphics processing units (GPUs), one or more application processors (e.g., for running or executing one or more software applications), and/or other processors. The at least one memory may include, for example, read-only memory (ROM), random access memory (RAM) (e.g., static RAM (SRAM)), electrically erasable programmable read-only memory (EEPROM), flash memory, one or more buffers, one or more databases, and/or other memory. The computer-executable instructions stored in or on the at least memory may be executed to perform one or more of the functions or operations described herein.

As previously mentioned, a digital twin is a digital model (e.g., a virtual model) that is designed to accurately reflect a real-world physical object (e.g., a UE, such as in the form of a vehicle), system, or process of a physical digital twin. A digital twin may serve as an effectively indistinguishable digital model of its associated counterpart physical twin (e.g., a vehicle), and may be used for simulation, integration, testing, monitoring, and maintenance of the associated counterpart physical twin. A digital twin may be used throughout the lifecycle (e.g., innovation, design, build, testing, and operation) of the physical twin that the digital twin represents to model and simulate operation of the physical twin. Thus, the digital twin may be created before the build of its associated physical twin. A digital twin of an existing physical twin may be used in real-time to determine modifications to be made to the physical twin and to synchronize the physical twin to its corresponding physical system.

A digital twin may update its status to be in accordance with the current status of its counterpart physical twin. In one or more examples, when sensors in the vicinity of the physical twin collect data, the sensor data may be utilized to update the digital twin in real time with the same state of the physical twin. A digital twin is meant to have an accurate representation of the physical twin's properties and states, which can include shape, position, status, and motion.

A digital twin may also be used for monitoring, diagnosis, and prognosis to optimize performance and utilization of its counterpart physical twin. Sensor data may be combined with historical data and simulation learning to improve the outcome of the prognosis. Therefore, intelligent maintenance systems may employ digital twins to determine causes of issues and improve productivity. In one or more examples, digital twins of autonomous vehicles and their associated sensors along with digital twins of the associated environment have been used for development, testing, and validation challenges for the automotive applications, especially when the related algorithms are based on machine learning (ML) approaches that require extensive training data and validation data sets.

There are various different types of digital twins, and it is common to have different types of digital twins co-exist with each other. Different types of digital twins may include, but are not limited to, unit twins, system twins, and environment twins. When two or more components work together, they form a unit, such as user equipment (UE), which may be in the form of a vehicle. A unit twin, such as a digital twin of a UE (uDT), may be used to study the interaction of those components, which may create a wealth of performance data that can be processed and then turned into actionable insights. A system twin, such as an operating digital twin (oDT), may show how different units (e.g., UEs) function together to form an entire functioning system. System twins can provide visibility regarding the interaction of units, and may suggest performance enhancements. An environment twin, which is a digital twin of the environment (eDT), may be used to model a real-world environment of units (e.g., UEs). Environment twins may be used to shows how the environment impacts the units (e.g., UEs).

Physical entities (e.g., a UE, such as in the form of a vehicle) can be impacted by changes within their real-world environment. The nature of changes in the real-world environment can include temporary changes (e.g., roadblocks and/or parked cars), permanent changes (e.g., new structures and/or downed trees), recurrent changes (e.g., traffic patterns and/or changes in visibility), non-recurrent changes (e.g., temporary structures), and/or periodic changes (having a periodicity). These changes can have varying levels of impact (e.g., a high impact or a low impact) to the physical entities. In one or more examples, a change in weather of the environment (e.g., when a temperature drops below 32 degrees Fahrenheit) can have a smaller impact (e.g., a low impact) on visibility and vision-based applications that rely on a digital twin. However, the same change in weather may have a greater impact (e.g., a high impact) on road safety applications that relay on the digital twin models.

Digital twins of physical entities (e.g., uDTs) along with digital twins of the environment (e.g., eDTs) of the physical entities and digital twins of the systems (e.g., oDTs) of the physical entities may be used to determine whether any updates (e.g., changes in a route of travel for a physical entity in the form of a vehicle) are needed for any of the physical entities and any of their associated digital twins due to changes within the environment.

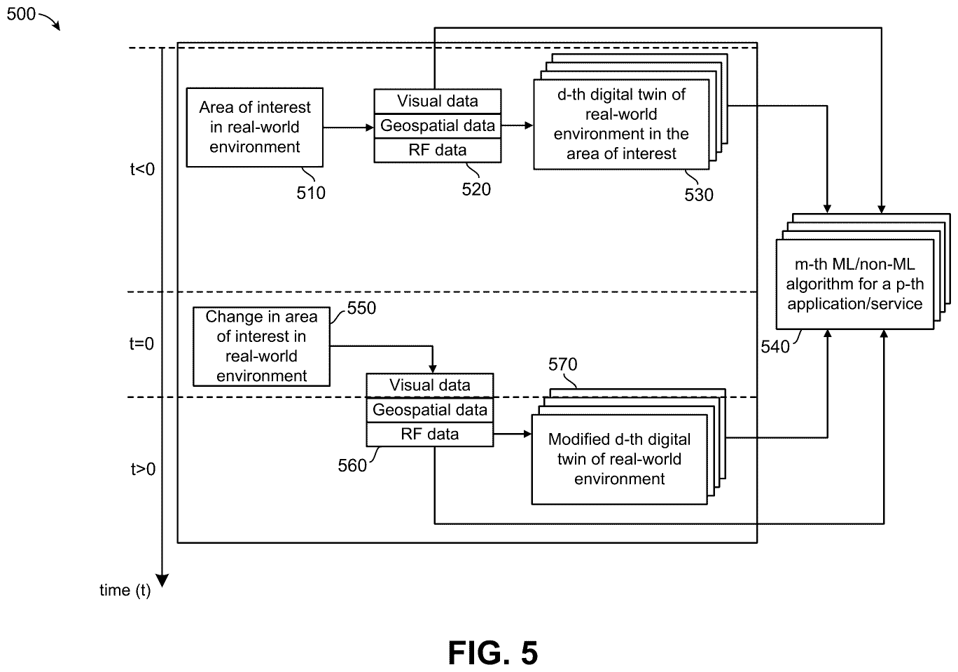

FIG. 5 illustrates an example of a process 500 for the creation/update of one or more digital twins for an area of interest in a real-world environment. In one or more examples, a digital twin, such as an eDT, may be created/updated for an area of interest in the environment. A set of data elements, which can include visual data, geospatial data, radio frequency (RF) data, and/or other data elements of the environment can be acquired. In one or more examples, sensors associated with the UE (e.g., the vehicle) can obtain (e.g., sense) those data elements. The post-processed representation of the data elements can be used to create/update the digital twin (e.g., eDT). For example, because the sensed data elements are related to the environment, the digital twin can be considered a digital twin of the environment (eDT). As described herein, a digital twin of a UE (uDT) can be created along with (or even before) the physical twin of the UE is manufactured. In some cases, each vehicle's uDT can be updated based on the vehicle UE's internal sensors and other mechanisms that monitor the health of the vehicle (e.g., monitoring the tire pressure, air filter, etc. of the vehicle).

The process 500 can be performed for the creation of one or more digital twin-based models for the area of interest in the real-world environment. In FIG. 5, the process 500 is shown to be divided into three different portions of time, including a time before the change occurs (e.g., t<0), the time when the change occurs (e.g., t=0), and the time after the change occurs (e.g., t>0).

At a time t<0, before a change in the area of interest in the real-world environment occurs and such a change is experienced by a UE (e.g., a vehicle), the area of interest within the real-world environment (at block 510) of the UE can be mapped to one or more (e.g., dth number of) digital twins (at block 530) of the real world environment in the area of interest, based on (e.g., using) a set of data (at block 520). As such, the digital twins (at block 530) may have been created before the change event at t=0. In one or more examples, the set of data can include visual data, geospatial data, RF data, and/or other types of relevant data to the area of interest. In one or more examples, the set of data can be obtained from the area of interest of the real-world environment (e.g., obtained by sensors associated with the UE). One or more (e.g., mth number of) ML and/or non-ML algorithms (at block 540) and their corresponding hyperparameters and models can be trained for one or more (e.g., pth number of) relevant applications and/or services using, based on the set of data (at block 520) and the digital twins (at block 530). In one or more examples, the one or more ML and/or non-ML algorithms may be trained at a network entity (e.g., a central server, which may be configured to implement ML services), which may be located remotely from the UE.

At time t=0, the UE experiences a change in the area of interest of the real-world environment (at block 550). The change in the area of interest can be reflected in the set of data (at block 560). The set of data (at block 560) can be used to modify one or more (e.g., the dth number) of the digital twins (at block 570) of the real world environment in the area of interest. One or more (e.g., mth number of) ML and/or non-ML algorithms (at block 540) and their corresponding hyperparameters and models can be then trained (or used for inference) for one or more (e.g., pth number of) relevant applications and/or services using, based on the set of data (at block 560) and the digital twins (at block 570).

As such, in the process 500 of FIG. 5, at time t≥0, the changes in the visual, geospatial, and other data elements can be tracked, which can be done through a combination of devices, such as sensors at the UEs (e.g., vehicles and/or cellular devices) giving their channel state information. It may be a combination of devices (e.g., UEs) that might be in communication with a network entity (e.g., a central server) that are giving this trackable information. Further, these changes can then be propagated to each of the existing digital twins. Some examples of changes that may occur at time t=0 may include, but are not limited to, changes in weather, changes in road conditions, changes in traffic conditions, changes in visibility, incidents (e.g., a downed tree due to bad weather), snowbanks (e.g., which will be not instantaneous, but might last weeks), temporary installations (e.g., tents, work machinery), and parked cars (e.g., which may also last for a few hours).

Each of the digital twins (e.g., at block 570) can differ from each other based on factors. For example, the one or more digital twins may be distinguished based on fidelity of representation of the real-world environment, such as a granularity or resolution of the representation of the environment. For another example, the one or more digital twins may be distinguished based on the complexity and memory overhead at the location of storage. For example, a UE in the form of a vehicle may receive a simplified or localized version of a more detailed model stored at a network entity (e.g., a central server). As another example, the one or more digital twins may be distinguished based on how they will be further used in applications. For example, if a digital twin is only going to be utilized for wireless applications, visual data may not be needed to create the digital twin. However, geospatial data, terrain information, material information, and RF data may be used to populate that digital twin.

As previously mentioned, currently, digital twin systems do not take into account the nature and impact of changes in the real-world environment for determining the necessity of updates and the manner of updates (e.g., modifications) for the physical entities and their associated digital twins. Not determining the nature and impact of changes in the real-world environment before triggering an update (e.g., a modification) of one or more digital twins may lead to a large computational overhead (e.g., at any of the devices deployed at a central server that are tracking changes or propagating changes to the digital twins), a large communication overhead (e.g., for any of the UEs that are tracking changes in the real-world environment), and a large time-complexity of updating recurrent changes (e.g., that have a high impact on one or more applications and services).

Therefore, improved systems and techniques for real-time extrapolation and interactions of digital twin-based models and applications that take into account the nature and impact of changes in the real-world environment of the associated physical entities can be useful.

As noted previously, according to one or more aspects, systems and techniques are described herein that provide real-time extrapolation and interactions of digital twin-based models and applications. In one or more examples, the systems and techniques provide solutions that take into account the nature (e.g., temporary, permanent, recurrent, non-recurrent, and/or periodic) and impact (e.g., high impact or low impact) of changes in a real-world environment of physical entities before triggering an update (e.g., a modification) to one or more associated digital twins due to the changes.

In one or more examples, during operation of the systems and techniques for wireless communications, a network entity (e.g., including a server configured to implement ML services) can determine one or more tracking elements based on detection of a change within an area of interest in a real-world environment of a UE (e.g., a vehicle). The one or more tracking elements can include estimates of an impact of the change to one or more applications in the area of interest and one or more characteristics of the change. The network entity can determine, based on the impact of the change and the one or more characteristics of the change, whether to determine (e.g., select, create, obtain, etc.) one or more digital twin models for a target area within the area of interest or to modify one or more existing digital twin models for the area of interest. The one or more tracking elements can further include the target area, where the target area can be smaller in size than the area of interest. The network entity may receive from the UE a set of data elements associated with the area of interest, where the set of data elements may include visual data, geospatial data, and/or RF data. The determination of the one or more tracking elements may be based on the set of data elements. The one or more characteristics of the change may be a temporary change, a permanent change, a recurrent change, a non-recurrent change, and/or a periodic change. The impact of the change may be a first impact or a second impact, where the first impact can be a higher impact than the second impact. The one or more digital twin models for the target area can be determined (e.g., selected, created, obtained, etc.) based on the one or more characteristics of the change being the temporary change and the impact of the change being the first impact. The one or more existing digital twin models for the area of interest can be modified, based on the one or more characteristics of the change being the permanent change and based on the impact of the change being the first impact. The one or more digital twin models can be determined (e.g., selected, created, obtained, etc.) based on the one or more applications. The one or more digital twin models can include a virtual model of the UE, a virtual model of the environment, and/or a virtual model of a system comprising the UE.

In one or more examples, during operation of the systems and techniques for wireless communications, UE (e.g., a vehicle) can transmit a digital twin interaction request to a network entity (e.g., including a server configured to perform ML) based on detection of a change in an area of interest in a real-world environment of the UE. The UE can receive a set of parameters from the network entity, based on the network entity receiving the digital twin interaction request. The UE can transmit a set of data elements to the network entity based on the set of parameters. The UE can receive from the network entity an output of a server configured for machine learning, based on the set of parameters and the set of data elements.

Currently, there are issues with real-time updates to digital twins (e.g., including an eDT and an oDT). One issue is that extrapolation of an existing eDT needs to include any changes detected in the environment. As mentioned, the changes in the environment may be detected and tracked using sensors associated with a UE (e.g., a vehicle or wireless device) and sensors associated with a central entity (e.g., a camera deployed at an RSU). The tracked changes may be in the format of visual data elements, RF data elements, geospatial data elements, and/or other types of relevant data elements. The tracked changes then need to be mapped to the eDT and to each other (e.g., considering properties, such as latitude, longitude, daytime, and visibility).

Another issue is the interaction of an eDT with a uDT that is needed to create an oDT. For example, in this case, the interaction between a UE (e.g., a vehicle) and terrain may be considered. The UE (e.g., vehicle) may signal change (e.g., which may be in the format of a digital twin) in the area of interest (e.g., road of the terrain) in the real-world environment of the UE. The signaled changes then need to be appropriately mapped to the eDT. Properties, such as latitude, longitude, altitude, etc., may be used to help locate the part (e.g., road) of the terrain where the UE is detecting a change. In one or more examples, any additional services and/or applications that utilize digital twins also need to be updated accordingly on the basis of extrapolation and/or interactions.

To address these issues, the systems and techniques provide an assessment and classification of the tracked and/or signaled changes. In one or more examples, the systems and techniques can determine the nature (e.g., characteristics) and the magnitude of impact that the changes have on the current eDT and relevant applications. Without taking into account the nature (e.g., characteristics) and impact of the changes, services utilizing the digital twins can incur a significant overhead when repeatedly accounting for the recurrent changes, a significant overhead when accounting for the changes to the real-world environment that have a minimal impact on one or more applications, and a deterioration of performance metrics if the tracked and/or signaled changes are not accounted for in the current algorithms for one or more applications.

In one or more aspects, the extrapolation of an existing eDT may be performed to include any changes detected in the environment. As mentioned, the changes in the environment may be detected and tracked by using sensors associated with the UE (e.g., vehicle or wireless device) and sensors associated with a central network entity such as an RSU. In one or more examples, the sensors may be configured with certain device metrics, such as field of view, image properties, channel state information, and/or RF range of the sensors. The tracked changes can be in the form of visual data elements, RF data elements, geospatial data elements, and/or other types of data elements. The tracked changes can be transmitted by the UE to a network entity (e.g., a central server). The network entity can then map the tracked changes (e.g., grouped together by association) to each other as well as to the eDT (e.g., appropriate changes can be made to the eDT).

In one or more examples, the nature (e.g., characteristics) of the change in the environment may be temporary, but recurrent. For example, a change in the distribution of parked cars may be temporary, but recurrent. The extrapolation of the eDT without taking into account the nature (e.g., characteristics) of the change can result in a large overhead due to frequent updates to one or more digital twin models as well as a large overhead due to frequent updates to one or more ML and/or non-ML algorithms that rely on the selection of the digital twin models.

In some examples, the nature (e.g., characteristics) of the change in the environment may be temporary, but non-recurrent. For example, changes in obstacles (e.g., tents, snowbanks, and/or roadblocks) can be temporary, but non-recurrent. The algorithms may be updated for a larger target area, however the change or the obstacle is restricted to a smaller target area. For example, in applications through wireless communications and traffic management, the larger target area is unaffected, but the smaller target area would be affected. As such, the range of impact (e.g., a characteristic) needs to be understood. For example, parking a car might be completely unimpacted by whether there is snow or whether there are roadblocks.

The extrapolation of the eDT without taking into account the nature (e.g., characteristics) of the change can result in a large overhead of mapping tracked changes for a larger area of interest instead of a smaller affected target area, a large overhead of updating algorithms that are not impacted by the changes, and a large overhead of updating algorithms for the larger area of interest (e.g., for applications related to wireless communications, traffic management, etc.).

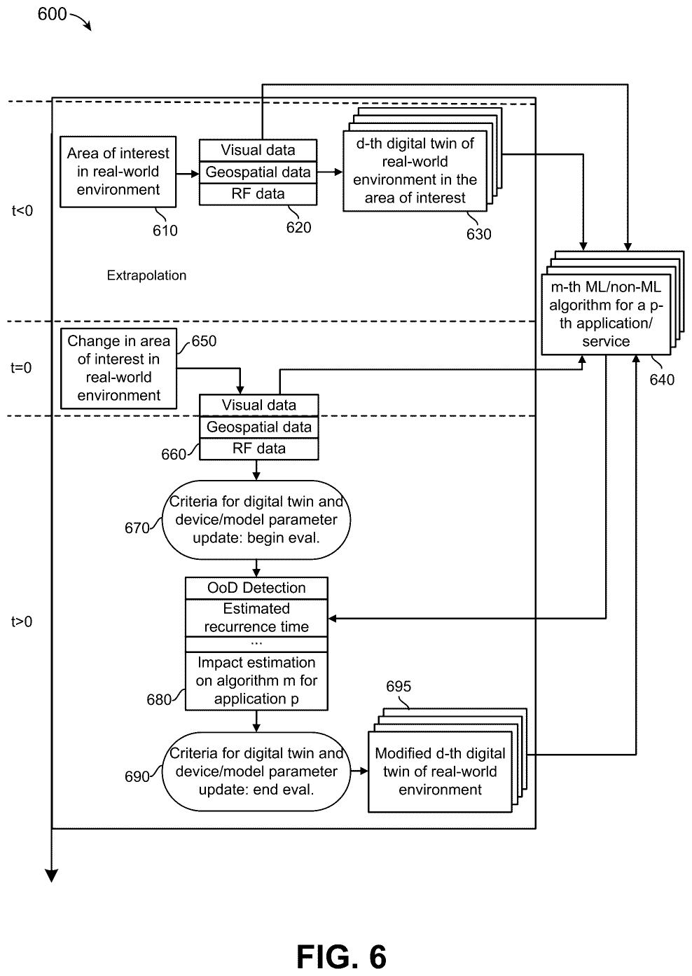

FIG. 6 is a diagram illustrating an example of a process 600 for the real-time extrapolation of digital twin-based models and applications. In FIG. 6, the process 600 is shown to be divided into three different portions of time, including a time before the change occurs (e.g., t<0), a time at which the change occurs (e.g., t=0), and a time after the change has occurred (e.g., t>0).

During time t<0, before a change in the area of interest in the real-world environment occurs and is experienced by a UE (e.g., a vehicle), the area of interest within the real-world environment (at block 610) of the UE may be mapped to one or more (e.g., dth number of) digital twins (at block 630) of the real world environment in the area of interest, based on (e.g., using) a set of data (at block 620), which may include visual data, geospatial data, RF data, and/or other types of relevant data to the area of interest. Thus, the digital twins (at block 630) may be created at the time t<0. In some examples, the set of data may be obtained from the area of interest of the real-world environment (e.g., obtained by sensors associated with the UE). One or more (e.g., mth number of) ML and/or non-ML algorithms (at block 640) and their corresponding hyperparameters and models may be trained for one or more (e.g., pth number of) relevant applications and/or services using, based on the set of data (at block 620) and the digital twins (at block 630). In one or more examples, the one or more ML and/or non-ML algorithms can be trained on a network entity (e.g., a central server, which may be configured to perform ML), which can be remote from the UE.

At time t=0, the UE experiences a change in the area of interest of the real-world environment (at block 650). The change in the area of interest may be reflected in the set of data (at block 660), which may include visual data, geospatial data, RF data, and/or other types of relevant data to the area of interest. At time t>0 (or in some cases at time t≥0), the evaluation can begin (at block 670), where the set of data (at block 660) can be analyzed in terms of criteria for a parameter update for the one or more digital twins as well as for any device or model parameters. For instance, according to some aspects, the detection of a change in the area of interest at t=0 can trigger the evaluation at t>0. According to some aspects, if the detection and the evaluation are not independent processes, then the evaluation can occur at t≥0. The evaluation can be performed in terms of criteria including an out-of-distribution (OoD) detection, an estimated recurrence time, an impact estimation on one or more (e.g., mth number of) algorithms and one or more (e.g., pth number of) applications (at block 680). In one or more examples, an OoD detection may be a detection for a parameter that occurs out of an expected range and/or normal distribution for that particular parameter. Once the criteria for the digital twin update, device parameter update, and/or model parameter update are satisfied (at block 690), the modification for the appropriate one or more (e.g., dth number of) digital twins of the real world-environment (at block 695) can be triggered. However, if the criteria are not satisfied, no subsequent changes to the relevant digital twins and/or their relevant algorithms in ML or non-ML areas can be made.

In one or more examples, the nature (e.g., characteristics) of the change in the environment may be temporary, but recurrent. For an example, a change in a distribution of parked cars may be temporary, but recurrent. Digital twin models, optimal ML algorithms, and/or optimal non-ML algorithms may be determined (e.g., selected, created, obtained, etc.) based on the hyperparameters resulting from the approximation based on the distribution of parked cars.

In some examples, the nature (e.g., characteristics) of the change in the environment may be temporary, but non-recurrent. For example, changes in obstacles (e.g., tents, snowbanks, and/or roadblocks) can be temporary, but non-recurrent. An estimation of impact on applications related to wireless communications, traffic management, etc. can be evaluated. The changes can be evaluated to determine whether the changes have a non-recurrent nature. In one or more examples, the sets of data (e.g., including visual data and RF data) can be used to create and store temporary digital twin models for a smaller area of interest to be used along with the original digital twin models for the larger area of interest.

In one or more aspects, the interaction of an eDT with a uDT (e.g., a digital twin of a UE, such as a vehicle) may involve changes being signaled (e.g., instead of being tracked) by the uDT (e.g., to a network entity). In one or more examples, the signaling may be in the form of a request, such as an advanced driver assistance system (ADAS) request. In one or more examples, the changes may be in the form of a digital twin. The signaled changes may then be mapped to the eDT.

For example, a UE (e.g., vehicle) may have a digital twin model of itself stored locally. The UE's digital twin (uDT) may include UE properties, such as vehicle dimensions, vehicle shape, tire pressure, fuel levels, velocity, acceleration, roll, pitch, and/or yaw. The environment's digital twin (eDT) may include environment information, such as pothole information, road incline information, terrain information, and/or precipitation information. In response to receiving a digital twin-based request (e.g., an ADAS request) from the uDT, if the nature of the change on the oDT were not computed, there can be a large overhead in the identification of target areas currently relevant to the uDT within the larger target area and/or a misidentification of the appropriate algorithms for the service and applications (e.g., such as when not accounting for precipitation, and/or such as when the selection of algorithms assumes average tire pressure and does not account for poor and/or imbalanced tire pressures).

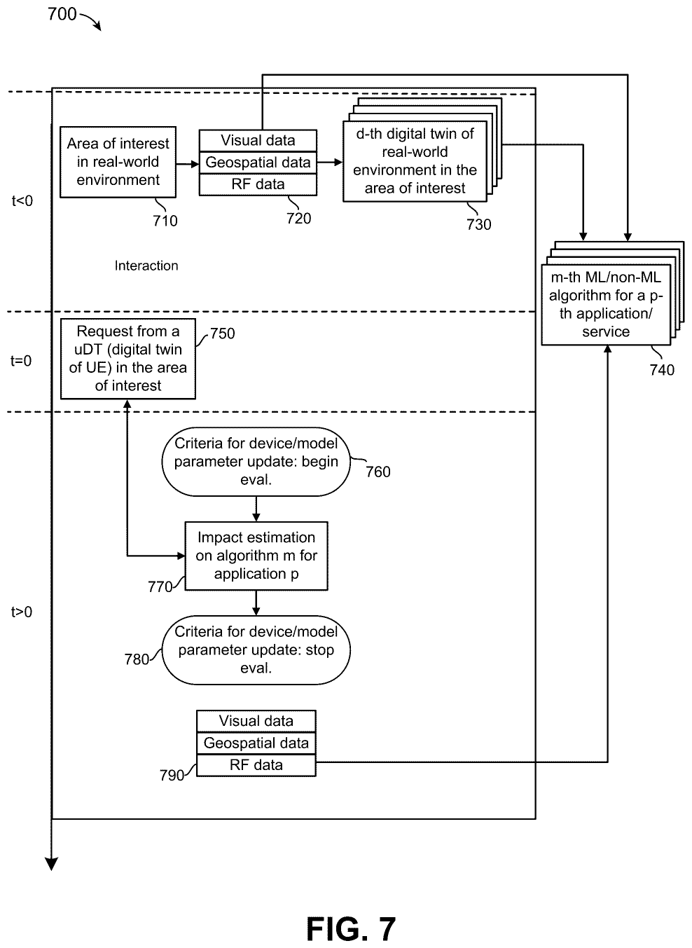

FIG. 7 is a diagram illustrating an example of a process 700 for the real-time interactions of digital twin-based models and applications. In FIG. 7, the process 700 is illustrated to be divided into three different portions of time, including a time before the change occurs (e.g., t<0), the time when the change occurs (e.g., t=0), and the time after the change occurs (e.g., t>0).

At a time t<0, before a change in the area of interest in the real-world environment occurs and such a change is experienced by a UE (e.g., a vehicle), the area of interest within the real-world environment (at block 710) of the UE can be mapped to one or more (e.g., dth number of) digital twins (at block 730) of the real world environment in the area of interest, based on (e.g., using) a set of data (at block 720), which may include visual data, geospatial data, RF data, and/or other types of relevant data to the area of interest. As such, the digital twins (at block 730) may have been created before the change event at t=0. In some examples, the set of data can be obtained from the area of interest of the real-world environment (e.g., obtained by sensors associated with the UE). One or more (e.g., mth number of) ML and/or non-ML algorithms (at block 740) and their corresponding hyperparameters and models can be trained for one or more (e.g., pth number of) relevant applications and/or services using, based on the set of data (at block 720) and the digital twins (at block 730). The one or more ML and/or non-ML algorithms may be trained at a network entity (e.g., a central server, which may be configured to implement ML services), which may be remote from the UE.

At time t=0, the UE experiences a change in the area of interest within the real-world environment. In response to experiencing a change, a digital twin of the UE (e.g., uDT) can send a request to a network entity (e.g., including a server configured for ML) at block 750. In response to receiving the request at time t=0, an evaluation of criteria for whether a device parameter and/or a model parameter update is required can be performed at time t>0 (at block 760). The criteria can include an estimate of an impact of the change on one or more (e.g., mth number of) algorithms for one or more (e.g., pth number of) applications (at block 770). If the criteria are satisfied, then based on the sets of data (at block 790), the appropriate ML and/or non-ML algorithms can be selected and applied to the request of the uDT. However, if the criteria are not satisfied, the evaluation can be stopped (at block 780).

For an example, a UE (e.g., vehicle) may have a digital twin model of itself (e.g., uDT) stored locally. The uDT can include properties of the UE, such as tire pressure, fuel levels, velocity, and/or acceleration. The environment's digital twin (e.g., eDT) can include information about potholes, road incline, terrain, and/or precipitation. In response to a digital twin-based request (e.g., an ADAS request), a network entity (e.g., a central server) can compute a determination of a target area within the area of interest based on a sliding window, an estimation of hyperparameters to determine an optimal reduction (if any exist) of the larger digital twin models, and/or an estimation of hyperparameters for the selection of optimal ML algorithms and/or non-ML algorithms.

In one or more aspects, for performing an extrapolation of an existing eDT to include any changes detected in the environment, a network entity (e.g., a central server) can determine a first selection of model parameters and device parameters, which may be derived using a first set of hyperparameters prior to the change in the environment which triggers the extrapolation. The network entity can receive, for an area of interest, a first set of data elements from a first UE prior to the change in the environment. In one or more examples, the data elements can be related to visual, wireless, geospatial, and other properties in the area of interest. The network entity can then transmit, to the first UE, an output of a central ML server (of the network entity), which can be based on the first selection of model parameters and device parameters. Upon a change occurring in the environment, the network entity can then receive, for an area of interest, a second set of data elements from a combination of central devices and UE devices (e.g., including the first UE). The network entity can determine, from the second set of data elements and the central ML server, a first indication of an OoD detection. Upon obtaining the OoD indication, the network entity can determine, from the second set of data elements and the central ML server, a first set of tracking elements.

In one or more examples, the tracking elements can be determined independently for one or more of the applications and/or services, when utilizing one or more of the digital twin models. In some examples, the tracking elements can include estimates of a smaller target area most relevant to the OoD indication within the area of interest and estimates of impact to services and/or applications in the estimated target area. In one or more examples, the tracking elements can include indications of the recurrent versus non-recurrent nature, periodicity, and/or the temporary versus permanent nature of the OoD indication.

Upon obtaining an indication of temporary nature and estimated impact, the network entity can receive from one or more devices in the smaller target area, a third set of data elements to obtain one or more smaller digital twin models relevant to the target area. Upon obtaining an indication of permanent nature and estimated impact, the network entity can receive from one or more devices in the smaller target area, a third set of data elements to modify one or more digital twin models relevant in the area of interest.

The network entity can transmit the one or more modified digital twin models to the first UE. In one or more examples, the tracking elements can include a second set of hyperparameters. The network entity can transmit a second selection of model parameters and device parameters, which may be derived using a second set of hyperparameters, to the first UE. The network entity can then receive a fourth set of data elements from the first UE. The network entity can transmit the output of the central ML server, which is based on the second selection of model parameters and device parameters, to the first UE.

In one or more aspects, for the interaction of an eDT with a uDT (e.g., a digital twin of a UE, such as a vehicle), a network entity (e.g., a central server) a network entity (e.g., a central server) can determine a first selection of model parameters and device parameters, which may be derived using a first set of hyperparameters. The network entity can receive, for an area of interest, a first set of data elements from a first UE. In one or more examples, the first set of data elements can be related to visual, wireless, geospatial, and/or other properties in the area of interest. The network entity can transmit an output of the central ML server, based on the first selection of model parameters and device parameters, to the first UE. The network entity can then receive a first digital twin interaction request from a first UE. The network entity can then determine, from the first set of data elements and the central ML server, a first set of tracking elements.

In one or more examples, the tracking elements may be determined independently for one or more of the applications and/or services when utilizing one or more of the digital twin models. In some examples, the tracking elements can include estimates of a smaller target area most relevant to the first digital twin interaction request within the area of interest and estimates of impact to services and/or applications in the estimated target area. In one or more examples, the tracking elements can include a second set of hyperparameters. The network entity can then transmit a second selection of model parameters and device parameters, derived using a second set of hyperparameters, to the first UE. The network entity can then receive a second set of data elements from the first UE. The network entity can then transmit an output of the central ML server, based on the second selection of model parameters and device parameters, to the first UE.

In one or more aspects, for performing an extrapolation of an existing eDT to include any changes detected in the environment, a UE (e.g., vehicle) can receive a first selection of model parameters and device parameters from the network entity (e.g., a central server). The UE can then transmit a first set of data elements to the network entity. In one or more examples, the set of data elements are related to the visual, wireless, geospatial, and/or other properties in the area of interest. The UE can receive a first set of one or more modified digital twin models from the network entity. The UE can then receive a second selection of model parameters and device parameters from the network entity.

In one or more aspects, for the interaction of an eDT with a uDT (e.g., a digital twin of a UE, such as a vehicle), a UE (e.g., vehicle) can receive a first selection of model parameters and device parameters from the network entity. The UE can then transmit a first set of data elements to the network entity. In one or more examples, the set of data elements is related to to the visual, wireless, geospatial, and/or other properties in the area of interest. The UE can receive the output of the central ML server, based on the first selection of model parameters and device parameters, from the network entity. The UE can receive the output of the central ML server, based on the first selection of model parameters and device parameters, from the network entity. The UE can then transmit a first digital twin interaction request to the network entity. The UE can receive a second selection of model parameters and device parameters from the network entity based on the first digital twin interaction request, the uDT, the eDT, and the resulting oDT. The UE can then transmit a second set of data elements to the network entity. The UE can receive the output of the central ML server, based on the second selection of model parameters and device parameters, from the network entity. In one or more examples, the UE may also receive a third selection of model parameters and device parameters from the network entity.

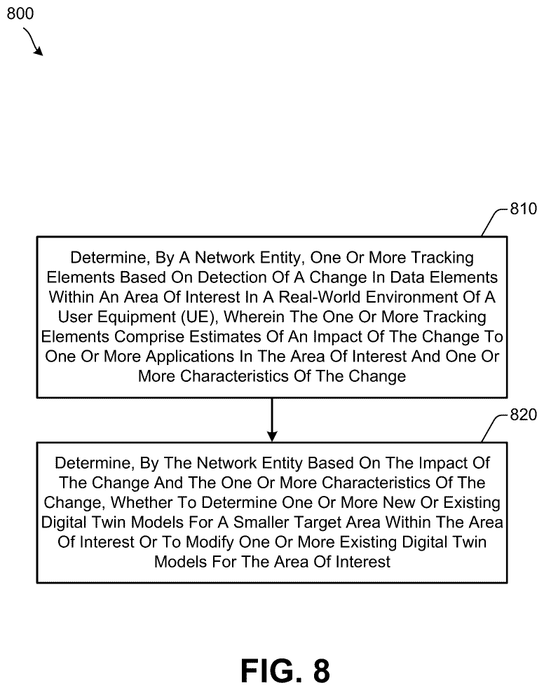

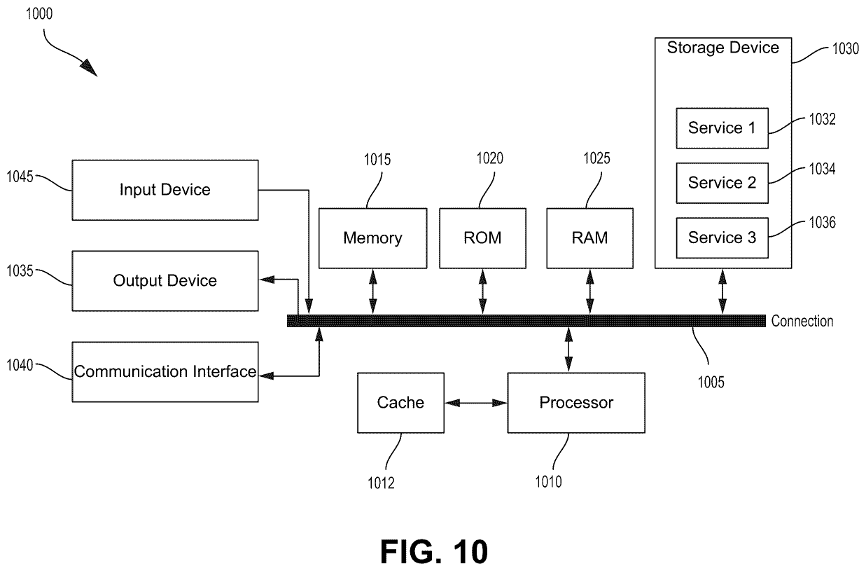

FIG. 8 is a flow chart illustrating an example of a process 800 for real-time extrapolation of digital twin-based models and applications. The process 800 can be performed by a network entity (e.g., a device such as a server configured to perform one or more ML or non-ML algorithms or operations, a computing device or computing system 1000 of FIG. 10, or other network entity) or by a component or system (e.g., a chipset, one or more processors such as one or more central processing units (CPUs), digital signal processors (DSPs), graphics processing units (GPUs), any combination thereof, and/or other type of processor(s), or other component or system) of the computing device. The operations of the process 800 may be implemented as software components that are executed and run on at least one processor (e.g., processor 1010 of FIG. 10 or other processor(s)). Further, the transmission and reception of signals by the computing device in the process 800 may be enabled, for example, by one or more antennas and/or one or more transceivers such as one or more wireless transceiver(s) (e.g., the transmit processor 220, the Tx MIMO processor 230, the modulator/demodulator 232a, the antenna 234a, and/or other component of the base station 102 of FIG. 2).

At block 810, the network entity (or component thereof, such as at least one processor) can determine one or more tracking elements based on detection of a change in data elements within an area of interest in a real-world environment of a network device. In some cases, the network device is a user equipment (UE), such as a vehicle or another wireless device. For example, the one or more tracking elements can include estimates of an impact of the change to one or more applications in the area of interest and one or more characteristics of the change. In some cases, the one or more tracking elements further include an estimation of the target area, wherein the target area is smaller in size than the area of interest.

In some aspects, the network entity (or component thereof, such as at least one receiver or transceiver) can receive, from the network device (e.g., the UE), a set of data elements associated with the area of interest. For instance, the set of data elements can include visual data, geospatial data, radio frequency (RF) data, any combination thereof, and/or other data. In some cases, the network entity (or component thereof) can determine the one or more tracking elements based on the set of data elements.

At block 820, the network entity (or component thereof, such as the at least one processor) can determine, based on the impact of the change and the one or more characteristics of the change, whether to determine one or more new or existing digital twin models for a smaller target area within the area of interest or to modify one or more existing digital twin models for the area of interest. In some cases, the network entity (or component thereof, such as the at least one processor) can determine the one or more new or existing digital twin models based on the one or more applications. In some cases, the one or more new or existing digital twin models may include a virtual model of the network device (e.g., the UE), a virtual model of the real-world environment, a virtual model of a system comprising the network device, any combination thereof, etc.

In some cases, the one or more characteristics of the change is a temporary change, a permanent change, a recurrent change, a non-recurrent change, a periodicity, any combination thereof, an/or other characteristic(s). In such cases, the impact of the change can include a first impact or a second impact, where the first impact is a higher impact than the second impact. In some aspects, the network entity (or component thereof, such as the at least one processor) can determine the one or more new or existing digital twin models for the target area based on the one or more characteristics of the change being the temporary change and the impact of the change being the first impact. In some aspects, the network entity (or component thereof, such as the at least one processor) can modify the one or more existing digital twin models for the area of interest based on the one or more characteristics of the change being the permanent change and based on the impact of the change being the first impact.

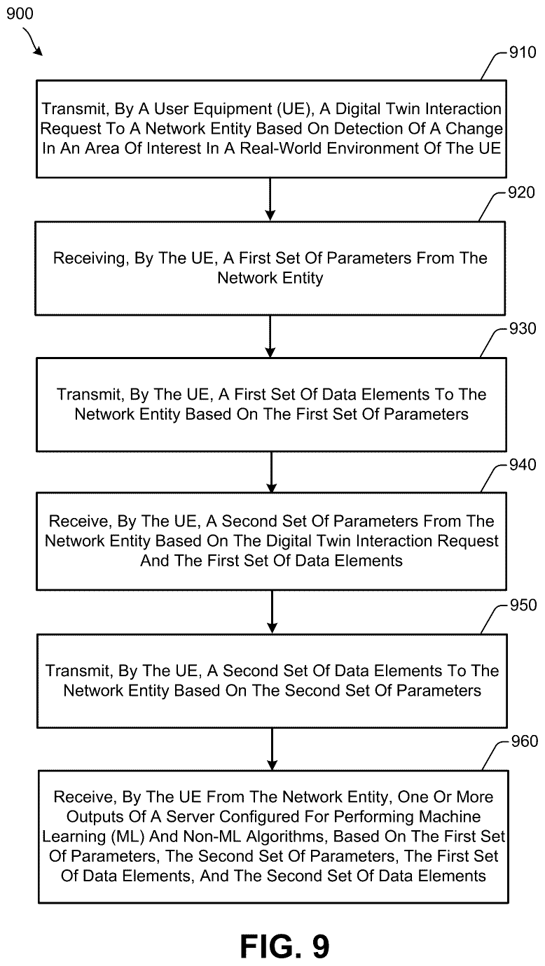

FIG. 9 is a flow chart illustrating an example of a process 900 for real-time interactions of digital twin-based models and applications. The process 900 can be performed by a network device (e.g., user equipment (UE), such as a vehicle, a computing device or computing system 1000 of FIG. 10, or other network device) or by a component or system (e.g., a chipset, one or more processors such as one or more central processing units (CPUs), digital signal processors (DSPs), graphics processing units (GPUs), any combination thereof, and/or other type of processor(s), or other component or system) of the computing device. The operations of the process 900 may be implemented as software components that are executed and run on one or more processors (e.g., processor 1010 of FIG. 10 or other processor(s)). Further, the transmission and reception of signals by the computing device in the process 900 may be enabled, for example, by one or more antennas and/or one or more transceivers such as one or more wireless transceiver(s) (e.g., the transmit processor 264, the Tx MIMO processor 266, the modulator/demodulator 254a, the antenna 252a, and/or other component of the user equipment 104 of FIG. 2).

At block 910, the network device (or component thereof, such as at least one transmitter or transceiver) can transmit a digital twin interaction request to a network entity based on detection of a change in an area of interest in a real-world environment of the network device. For instance, the network entity can include a server or other network entity configured for performing one or more ML algorithms or operations.

At block 920, the network device (or component thereof, such as at least one receiver or transceiver) can receive a first set of parameters from the network entity. In some cases, the first set of parameters comprises model parameters, device parameters, and/or other parameters.

At block 930, the network device (or component thereof, such as at least one transmitter or transceiver) can transmit a first set of data elements to the network entity based on the first set of parameters. In some cases, the first set of data elements include visual data, geospatial data, radio frequency (RF) data, any combination thereof, and/or other data.

At block 940, the network device (or component thereof, such as at least one receiver or transceiver) can receive a second set of parameters from the network entity based on the digital twin interaction request and the first set of data elements.

At block 950, the network device (or component thereof, such as at least one transmitter or transceiver) can transmit a second set of data elements to the network entity based on the second set of parameters.

At block 960, the network device (or component thereof, such as at least one receiver or transceiver) can receive, from the network entity, one or more outputs of a server configured for performing machine learning (ML) and non-ML algorithms, based on the first set of parameters, the second set of parameters, the first set of data elements, and the second set of data elements. For instance, the network device can perform any operations according to FIG. 6 and/or FIG. 7.

In some cases, the computing device of process 800 and process 900 may include various components, such as one or more input devices, one or more output devices, one or more processors, one or more microprocessors, one or more microcomputers, one or more cameras, one or more sensors, and/or other component(s) that are configured to carry out the steps of processes described herein. In some examples, the computing device may include a display, one or more network interfaces configured to communicate and/or receive the data, any combination thereof, and/or other component(s). The one or more network interfaces may be configured to communicate and/or receive wired and/or wireless data, including data according to the 3G, 4G, 5G, and/or other cellular standard, data according to the Wi-Fi (802.11x) standards, data according to the Bluetooth™ standard, data according to the Internet Protocol (IP) standard, and/or other types of data.

The components of the computing device of process 800 and process 900 can be implemented in circuitry. For example, the components can include and/or can be implemented using electronic circuits or other electronic hardware, which can include one or more programmable electronic circuits (e.g., microprocessors, graphics processing units (GPUs), digital signal processors (DSPs), central processing units (CPUs), and/or other suitable electronic circuits), and/or can include and/or be implemented using computer software, firmware, or any combination thereof, to perform the various operations described herein. The computing device may further include a display (as an example of the output device or in addition to the output device), a network interface configured to communicate and/or receive the data, any combination thereof, and/or other component(s). The network interface may be configured to communicate and/or receive Internet Protocol (IP) based data or other type of data.

The process 800 and process 900 are each illustrated as a logical flow diagram, the operations of which represent a sequence of operations that can be implemented in hardware, computer instructions, or a combination thereof. In the context of computer instructions, the operations represent computer-executable instructions stored on one or more computer-readable storage media that, when executed by one or more processors, perform the recited operations. Generally, computer-executable instructions include routines, programs, objects, components, data structures, and the like that perform particular functions or implement particular data types. The order in which the operations are described is not intended to be construed as a limitation, and any number of the described operations can be combined in any order and/or in parallel to implement the processes.

Additionally, process 800 and process 900 may be performed under the control of one or more computer systems configured with executable instructions and may be implemented as code (e.g., executable instructions, one or more computer programs, or one or more applications) executing collectively on one or more processors, by hardware, or combinations thereof. As noted above, the code may be stored on a computer-readable or machine-readable storage medium, for example, in the form of a computer program comprising a plurality of instructions executable by one or more processors. The computer-readable or machine-readable storage medium may be non-transitory.

FIG. 10 is a block diagram illustrating an example of a computing system 1000, which may be employed for real-time extrapolation and interactions of digital twin-based models and applications. In particular, FIG. 10 illustrates an example of computing system 1000, which can be for example any computing device making up internal computing system, a remote computing system, a camera, or any component thereof in which the components of the system are in communication with each other using connection 1005. Connection 1005 can be a physical connection using a bus, or a direct connection into processor 1010, such as in a chipset architecture. Connection 1005 can also be a virtual connection, networked connection, or logical connection.

In some aspects, computing system 1000 is a distributed system in which the functions described in this disclosure can be distributed within a datacenter, multiple data centers, a peer network, etc. In some aspects, one or more of the described system components represents many such components each performing some or all of the function for which the component is described. In some aspects, the components can be physical or virtual devices.

Example system 1000 includes at least one processing unit (CPU or processor) 1010 and connection 1005 that communicatively couples various system components including system memory 1015, such as read-only memory (ROM) 1020 and random access memory (RAM) 1025 to processor 1010. Computing system 1000 can include a cache 1012 of high-speed memory connected directly with, in close proximity to, or integrated as part of processor 1010.

Processor 1010 can include any general purpose processor and a hardware service or software service, such as services 1032, 1034, and 1036 stored in storage device 1030, configured to control processor 1010 as well as a special-purpose processor where software instructions are incorporated into the actual processor design. Processor 1010 may essentially be a completely self-contained computing system, containing multiple cores or processors, a bus, memory controller, cache, etc. A multi-core processor may be symmetric or asymmetric.

To enable user interaction, computing system 1000 includes an input device 1045, which can represent any number of input mechanisms, such as a microphone for speech, a touch-sensitive screen for gesture or graphical input, keyboard, mouse, motion input, speech, etc. Computing system 1000 can also include output device 1035, which can be one or more of a number of output mechanisms. In some instances, multimodal systems can enable a user to provide multiple types of input/output to communicate with computing system 1000.

Computing system 1000 can include communications interface 1040, which can generally govern and manage the user input and system output. The communication interface may perform or facilitate receipt and/or transmission wired or wireless communications using wired and/or wireless transceivers, including those making use of an audio jack/plug, a microphone jack/plug, a universal serial bus (USB) port/plug, an Apple™ Lightning™ port/plug, an Ethernet port/plug, a fiber optic port/plug, a proprietary wired port/plug, 3G, 4G, 5G and/or other cellular data network wireless signal transfer, a Bluetooth™ wireless signal transfer, a Bluetooth™ low energy (BLE) wireless signal transfer, an IBEACON™ wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

The communications interface 1040 may also include one or more range sensors (e.g., LIDAR sensors, laser range finders, RF radars, ultrasonic sensors, and infrared (IR) sensors) configured to collect data and provide measurements to processor 1010, whereby processor 1010 can be configured to perform determinations and calculations needed to obtain various measurements for the one or more range sensors. In some examples, the measurements can include time of flight, wavelengths, azimuth angle, elevation angle, range, linear velocity and/or angular velocity, or any combination thereof. The communications interface 1040 may also include one or more Global Navigation Satellite System (GNSS) receivers or transceivers that are used to determine a location of the computing system 1000 based on receipt of one or more signals from one or more satellites associated with one or more GNSS systems. GNSS systems include, but are not limited to, the US-based GPS, the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1030 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (e.g., Level 1 (L1) cache, Level 2 (L2) cache, Level 3 (L3) cache, Level 4 (L4) cache, Level 5 (L5) cache, or other (L #) cache), resistive random-access memory (RRAM/ReRAM), phase change memory (PCM), spin transfer torque RAM (STT-RAM), another memory chip or cartridge, and/or a combination thereof.

The storage device 1030 can include software services, servers, services, etc., that when the code that defines such software is executed by the processor 1010, it causes the system to perform a function. In some aspects, a hardware service that performs a particular function can include the software component stored in a computer-readable medium in connection with the necessary hardware components, such as processor 1010, connection 1005, output device 1035, etc., to carry out the function. The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

Specific details are provided in the description above to provide a thorough understanding of the aspects and examples provided herein, but those skilled in the art will recognize that the application is not limited thereto. Thus, while illustrative aspects of the application have been described in detail herein, it is to be understood that the inventive concepts may be otherwise variously embodied and employed, and that the appended claims are intended to be construed to include such variations, except as limited by the prior art. Various features and aspects of the above-described application may be used individually or jointly. Further, aspects can be utilized in any number of environments and applications beyond those described herein without departing from the broader scope of the specification. The specification and drawings are, accordingly, to be regarded as illustrative rather than restrictive. For the purposes of illustration, methods were described in a particular order. It should be appreciated that in alternate aspects, the methods may be performed in a different order than that described.

For clarity of explanation, in some instances the present technology may be presented as including individual functional blocks comprising devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the aspects in unnecessary detail. In other instances, well-known circuits, processes, algorithms, structures, and techniques may be shown without unnecessary detail in order to avoid obscuring the aspects.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

Individual aspects may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

Processes and methods according to the above-described examples can be implemented using computer-executable instructions that are stored or otherwise available from computer-readable media. Such instructions can include, for example, instructions and data which cause or otherwise configure a general purpose computer, special purpose computer, or a processing device to perform a certain function or group of functions. Portions of computer resources used can be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

In some aspects the computer-readable storage devices, mediums, and memories can include a cable or wireless signal containing a bitstream and the like. However, when mentioned, non-transitory computer-readable storage media expressly exclude media such as energy, carrier signals, electromagnetic waves, and signals per se.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof, in some cases depending in part on the particular application, in part on the desired design, in part on the corresponding technology, etc.

The various illustrative logical blocks, modules, and circuits described in connection with the aspects disclosed herein may be implemented or performed using hardware, software, firmware, middleware, microcode, hardware description languages, or any combination thereof, and can take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Examples of form factors include laptops, smart phones, mobile phones, tablet devices or other small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium comprising program code including instructions that, when executed, performs one or more of the methods, algorithms, and/or operations described above. The computer-readable data storage medium may form part of a computer program product, which may include packaging materials. The computer-readable medium may comprise memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

One of ordinary skill will appreciate that the less than (“<”) and greater than (“>”) symbols or terminology used herein can be replaced with less than or equal to (“≤”) and greater than or equal to (“≥”) symbols, respectively, without departing from the scope of this description.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” or “communicatively coupled to” refers to any component that is physically connected to another component either directly or indirectly, and/or any component that is in communication with another component (e.g., connected to the other component over a wired or wireless connection, and/or other suitable communication interface) either directly or indirectly.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, A and B and C, or any duplicate information or data (e.g., A and A, B and B, C and C, A and A and B, and so on), or any other ordering, duplication, or combination of A, B, and C. The language “at least one of” a set and/or “one or more” of a set does not limit the set to the items listed in the set. For example, claim language reciting “at least one of A and B” or “at least one of A or B” may mean A, B, or A and B, and may additionally include items not listed in the set of A and B. The phrases “at least one” and “one or more” are used interchangeably herein.

Claim language or other language reciting “at least one processor configured to,” “at least one processor being configured to,” “one or more processors configured to,” “one or more processors being configured to,” or the like indicates that one processor or multiple processors (in any combination) can perform the associated operation(s). For example, claim language reciting “at least one processor configured to: X, Y, and Z” means a single processor can be used to perform operations X, Y, and Z; or that multiple processors are each tasked with a certain subset of operations X, Y, and Z such that together the multiple processors perform X, Y, and Z; or that a group of multiple processors work together to perform operations X, Y, and Z. In another example, claim language reciting “at least one processor configured to: X, Y, and Z” can mean that any single processor may only perform at least a subset of operations X, Y, and Z.

Where reference is made to one or more elements performing functions (e.g., steps of a method), one element may perform all functions, or more than one element may collectively perform the functions. When more than one clement collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions.

Where reference is made to an entity (e.g., any entity or device described herein) performing functions or being configured to perform functions (e.g., steps of a method), the entity may be configured to cause one or more elements (individually or collectively) to perform the functions. The one or more components of the entity may include at least one memory, at least one processor, at least one communication interface, another component configured to perform one or more (or all) of the functions, and/or any combination thereof. Where reference to the entity performing functions, the entity may be configured to cause one component to perform all functions, or to cause more than one component to collectively perform the functions. When the entity is configured to cause more than one component to collectively perform the functions, each function need not be performed by each of those components (e.g., different functions may be performed by different components) and/or each function need not be performed in whole by only one component (e.g., different components may perform different sub-functions of a function).

The various illustrative logical blocks, modules, engines, circuits, and algorithm steps described in connection with the embodiments disclosed herein may be implemented as electronic hardware, computer software, firmware, or combinations thereof. To clearly illustrate this interchangeability of hardware and software, various illustrative components, blocks, engines, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as engines, modules, or components may be implemented together in an integrated logic device or separately as discrete but interoperable logic devices. If implemented in software, the techniques may be realized at least in part by a computer-readable data storage medium comprising program code including instructions that, when executed, performs one or more of the methods described above. The computer-readable data storage medium may form part of a computer program product, which may include packaging materials. The computer-readable medium may comprise memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein. In addition, in some aspects, the functionality described herein may be provided within dedicated software modules or hardware modules configured for encoding and decoding, or incorporated in a combined video encoder-decoder (CODEC).

Illustrative aspects of the disclosure include:

Aspect 1. A network entity for wireless communications, the network entity comprising: at least one memory; and at least one processor coupled to the at least one memory and configured to: determine one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and determine, based on the impact of the change and the one or more characteristics of the change, whether to determine one or more new or existing digital twin models for a smaller target area within the area of interest or to modify one or more existing digital twin models for the area of interest.

Aspect 2. The network entity of Aspect 1, wherein the one or more tracking elements further comprise an estimation of the target area, wherein the target area is smaller in size than the area of interest.

Aspect 3. The network entity of any of Aspects 1 or 2, wherein the at least one processor is configured to receive, from the UE, a set of data elements associated with the area of interest.

Aspect 4. The network entity of Aspect 3, wherein the set of data elements comprises at least one of visual data, geospatial data, or radio frequency (RF) data.

Aspect 5. The network entity of any of Aspects 3 or 4, wherein the at least one processor is configured to determine the one or more tracking elements based on the set of data elements.

Aspect 6. The network entity of any of Aspects 1 to 5, wherein: the one or more characteristics of the change is at least one of a temporary change, a permanent change, a recurrent change, a non-recurrent change, or a periodicity; and the impact of the change is one of a first impact or a second impact, and wherein the first impact is a higher impact than the second impact.

Aspect 7. The network entity of Aspect 6, wherein the at least one processor is configured to determine the one or more new or existing digital twin models for the target area based on the one or more characteristics of the change being the temporary change and the impact of the change being the first impact.

Aspect 8. The network entity of Aspect 6, wherein the at least one processor is configured to modify the one or more existing digital twin models for the area of interest based on the one or more characteristics of the change being the permanent change and based on the impact of the change being the first impact.

Aspect 9. The network entity of any of Aspects 1 to 8, wherein the at least one processor is configured to determine one or more new or existing digital twin models based on the one or more applications.

Aspect 10. The network entity of any of Aspects 1 to 9, wherein the network entity comprises a server configured to perform one or more machine learning (ML) operations.

Aspect 11. The network entity of any of Aspects 1 to 10, wherein the UE is a vehicle or another wireless device.

Aspect 12. The network entity of any of Aspects 1 to 11, wherein the one or more new or existing digital twin models comprise at least one of a virtual model of the UE, a virtual model of the real-world environment, or a virtual model of a system comprising the UE.

Aspect 13. A method for wireless communications, the method comprising: determining, by a network entity, one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and determining, by the network entity based on the impact of the change and the one or more characteristics of the change, whether to determine one or more new or existing digital twin models for a smaller target area within the area of interest or to modify one or more existing digital twin models for the area of interest.

Aspect 14. The method of Aspect 13, wherein the one or more tracking elements further comprise an estimation of the target area, wherein the target area is smaller in size than the area of interest.

Aspect 15. The method of any of Aspects 13 or 14, further comprising receiving, by the network entity from the UE, a set of data elements associated with the area of interest.

Aspect 16. The method of Aspect 15, wherein the set of data elements comprises at least one of visual data, geospatial data, or radio frequency (RF) data.

Aspect 17. The method of any of Aspects 15 or 16, wherein the determination of the one or more tracking elements is based on the set of data elements.

Aspect 18. The method of any of Aspects 13 to 17, wherein: the one or more characteristics of the change is at least one of a temporary change, a permanent change, a recurrent change, a non-recurrent change, or a periodicity; and the impact of the change is one of a first impact or a second impact, and wherein the first impact is a higher impact than the second impact.

Aspect 19. The method of Aspect 18, further comprising determining the one or more new or existing digital twin models for the target area based on the one or more characteristics of the change being the temporary change and the impact of the change being the first impact.

Aspect 20. The method of Aspect 18, further comprising modifying the one or more existing digital twin models for the area of interest based on the one or more characteristics of the change being the permanent change and based on the impact of the change being the first impact.

Aspect 21. The method of any of Aspects 13 to 20, wherein the one or more new or existing digital twin models are determined based on the one or more applications.

Aspect 22. The method of any of Aspects 13 to 21, wherein the network entity comprises a server configured to perform one or more machine learning (ML) operations.

Aspect 23. The method of any of Aspects 13 to 22, wherein the UE is a vehicle or another wireless device.

Aspect 24. The method of any of Aspects 13 to 23, wherein the one or more new or existing digital twin models comprise at least one of a virtual model of the UE, a virtual model of the real-world environment, or a virtual model of a system comprising the UE.

Aspect 25. A network device for wireless communications, the network device comprising: at least one memory; and at least one processor coupled to the at least one memory and configured to: output a digital twin interaction request for transmission to a network entity based on detection of a change in an area of interest in a real-world environment of the network device; receive a first set of parameters from the network entity; output a first set of data elements for transmission to the network entity based on the first set of parameters; receive a second set of parameters from the network entity based on the digital twin interaction request and the first set of data elements; output a second set of data elements for transmission to the network entity based on the second set of parameters; and receive, from the network entity, one or more outputs of a server configured for performing machine learning (ML) and non-ML algorithms, based on the first set of parameters, the second set of parameters, the first set of data elements, and the second set of data elements.

Aspect 26. The network device of Aspect 25, wherein the first set of parameters comprises at least one of model parameters and device parameters.

Aspect 27. The network device of any of Aspects 25 or 26, wherein the first set of data elements comprises at least one of visual data, geospatial data, or radio frequency (RF) data.

Aspect 28. The network device of any of Aspects 25 to 27, wherein the network entity comprises the server configured for ML.

Aspect 29. The network device of any of Aspects 25 to 28, wherein the network device is a vehicle or another wireless device.

Aspect 30. A method for wireless communications, the method comprising: transmitting, by a network device, a digital twin interaction request to a network entity based on detection of a change in an area of interest in a real-world environment of the network device; receiving, by the network device, a first set of parameters from the network entity; transmitting, by the network device, a first set of data elements to the network entity based on the first set of parameters; receiving, by the network device, a second set of parameters from the network entity based on the digital twin interaction request and the first set of data elements; transmitting, by the network device, a second set of data elements to the network entity based on the second set of parameters; and receiving, by the network device from the network entity, one or more outputs of a server configured for performing machine learning (ML) and non-ML algorithms, based on the first set of parameters, the second set of parameters, the first set of data elements, and the second set of data elements.

Aspect 31. The method of Aspect 30, wherein the first set of parameters comprises at least one of model parameters and device parameters.

Aspect 32. The method of any of Aspects 30 or 31, wherein the first set of data elements comprises at least one of visual data, geospatial data, or radio frequency (RF) data.

Aspect 33. The method of any of Aspects 30 to 32, wherein the network entity comprises the server configured for ML.

Aspect 34. The method of any of Aspects 30 to 33, wherein the network device is a vehicle or another wireless device.

Aspect 35. A non-transitory computer-readable medium having stored thereon instructions that, when executed by one or more processors, cause the one or more processors to perform operations according to any of Aspects 13 to 24.

Aspect 36. An apparatus for wireless communications, the apparatus including one or more means for performing operations according to any of Aspects 13 to 24.

Aspect 37. A non-transitory computer-readable medium having stored thereon instructions that, when executed by one or more processors, cause the one or more processors to perform operations according to any of Aspects 30 to 34.

Aspect 38. An apparatus for wireless communications, the apparatus including one or more means for performing operations according to any of Aspects 30 to 34.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.”

What is claimed is:

1. A network entity for wireless communications, the network entity comprising:
at least one memory; and
at least one processor coupled to the at least one memory and configured to:
determine one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and
determine, based on the impact of the change and the one or more characteristics of the change, whether to determine one or more new or existing digital twin models for a smaller target area within the area of interest or to modify one or more existing digital twin models for the area of interest.

2. The network entity of claim 1, wherein the one or more tracking elements further comprise an estimation of the target area, wherein the target area is smaller in size than the area of interest.

3. The network entity of claim 1, wherein the at least one processor is configured to receive, from the UE, a set of data elements associated with the area of interest.

4. The network entity of claim 3, wherein the set of data elements comprises at least one of visual data, geospatial data, or radio frequency (RF) data.

5. The network entity of claim 3, wherein the at least one processor is configured to determine the one or more tracking elements based on the set of data elements.

6. The network entity of claim 1, wherein:
the one or more characteristics of the change is at least one of a temporary change, a permanent change, a recurrent change, a non-recurrent change, or a periodicity; and
the impact of the change is one of a first impact or a second impact, and wherein the first impact is a higher impact than the second impact.

7. The network entity of claim 6, wherein the at least one processor is configured to determine the one or more new or existing digital twin models for the target area based on the one or more characteristics of the change being the temporary change and the impact of the change being the first impact.

8. The network entity of claim 6, wherein the at least one processor is configured to modify the one or more existing digital twin models for the area of interest based on the one or more characteristics of the change being the permanent change and based on the impact of the change being the first impact.

9. The network entity of claim 1, wherein the at least one processor is configured to determine one or more new or existing digital twin models based on the one or more applications.

10. The network entity of claim 1, wherein the network entity comprises a server configured to perform one or more machine learning (ML) operations.

11. The network entity of claim 1, wherein the UE is a vehicle or another wireless device.

12. The network entity of claim 1, wherein the one or more new or existing digital twin models comprise at least one of a virtual model of the UE, a virtual model of the real-world environment, or a virtual model of a system comprising the UE.

13. A network device for wireless communications, the network device comprising:
at least one memory; and
at least one processor coupled to the at least one memory and configured to:
output a digital twin interaction request for transmission to a network entity based on detection of a change in an area of interest in a real-world environment of the network device;
receive a first set of parameters from the network entity;
output a first set of data elements for transmission to the network entity based on the first set of parameters;
receive a second set of parameters from the network entity based on the digital twin interaction request and the first set of data elements;
output a second set of data elements for transmission to the network entity based on the second set of parameters; and
receive, from the network entity, one or more outputs of a server configured for performing machine learning (ML) and non-ML algorithms, based on the first set of parameters, the second set of parameters, the first set of data elements, and the second set of data elements.

14. The network device of claim 13, wherein the first set of parameters comprises at least one of model parameters and device parameters.

15. The network device of claim 13, wherein the first set of data elements comprises at least one of visual data, geospatial data, or radio frequency (RF) data.

16. The network device of claim 13, wherein the network entity comprises the server configured for ML.

17. The network device of claim 13, wherein the network device is a vehicle or another wireless device.

18. A method for wireless communications, the method comprising:
determining, by a network entity, one or more tracking elements based on detection of a change in data elements within an area of interest in a real-world environment of a user equipment (UE), wherein the one or more tracking elements comprise estimates of an impact of the change to one or more applications in the area of interest and one or more characteristics of the change; and
determining, by the network entity based on the impact of the change and the one or more characteristics of the change, whether to determine one or more new or existing digital twin models for a smaller target area within the area of interest or to modify one or more existing digital twin models for the area of interest.

19. The method of claim 18, further comprising receiving, by the network entity from the UE, a set of data elements associated with the area of interest, wherein the determination of the one or more tracking elements is based on the set of data elements.

20. A method for wireless communications, the method comprising:
transmitting, by a network device, a digital twin interaction request to a network entity based on detection of a change in an area of interest in a real-world environment of the network device;
receiving, by the network device, a first set of parameters from the network entity;
transmitting, by the network device, a first set of data elements to the network entity based on the first set of parameters;
receiving, by the network device, a second set of parameters from the network entity based on the digital twin interaction request and the first set of data elements;
transmitting, by the network device, a second set of data elements to the network entity based on the second set of parameters; and
receiving, by the network device from the network entity, one or more outputs of a server configured for performing machine learning (ML) and non-ML algorithms, based on the first set of parameters, the second set of parameters, the first set of data elements, and the second set of data elements.
